(19) United States
(12) Patent Application Publication
(10) Pub. No.: US 2026/0126490 A1
(43) Pub. Date: May 7, 2026

(54) BATTERY PARAMETER ESTIMATION USING REDUCED-ORDER AND/OR FULL-ORDER ELECTROCHEMICAL MODELS

(71) Applicants: LG ENERGY SOLUTION, LTD., Seoul (KR); THE REGENTS OF THE UNIVERSITY OF MICHIGAN, Ann Arbor, MI (US)

(72) Inventors: Wei LU, Ann Arbor, MI (US); Tianhan GAO, Ann Arbor, MI (US); Dong-Wook KOH, Daejeon (KR); Gwang Hoon JUN, Daejeon (KR); You Na KIM, Daejeon (KR)

(21) Appl. No.: 18/935,345

(22) Filed: Nov. 1, 2024

(51) Int. Cl. G01R 31/367; B60L 3/00; B60L 58/16; G01R 31/36; G01R 31/3842; G01R 31/392

(52) U.S. Cl. CPC G01R 31/367; B60L 3/0046; B60L 58/16; G01R 31/3648; G01R 31/3842; G01R 31/392

(57) ABSTRACT

This disclosure relates to systems, methods, and techniques for estimating battery parameters using a battery analysis system. In certain embodiments, the system receives current data for a battery cell, preprocesses the data to reduce frequency and amplitude, and executes a shallow estimation function using a reduced-order electrochemical model to estimate battery parameters based on the preprocessed data. In some embodiments, a deep estimation function, which utilizes a full-order electrochemical model, may be utilized to further refine the battery parameter estimates if higher accuracy is desired. Other embodiments are disclosed herein as well.

### TECHNICAL FIELD

This disclosure is related to systems, methods, and techniques for estimating battery parameters. In certain embodiments, the systems, methods, and techniques described herein can be executed to rapidly estimate battery parameters of one or more battery cells with high accuracy utilizing reduced-order and/or full-order electrochemical models.

### BACKGROUND

Battery management systems (BMSs) monitor and control the charging and discharging of rechargeable batteries. For example, a BMS may measure and regulate various parameters, such as voltage, current, temperature, and state of charge, for individual battery cells or entire battery packs. In some cases, the BMS also may perform functions like cell balancing, thermal management, and communication with external systems to optimize battery performance and longevity.

The rapid advancement of electric vehicles, and other battery-powered systems, has significantly increased the demands on battery performance and reliability. These vehicles and systems often require batteries to operate under diverse and challenging conditions, necessitating more sophisticated BMS technologies. Modern BMSs are expected to not only ensure safe operation, but also maximize battery efficiency, extend lifespan, and provide accurate real-time data for optimal system performance. As such, there is a growing need for advanced BMS solutions that can handle complex battery configurations, adapt to varying operational requirements, and integrate seamlessly with electric vehicles and/or other battery-powered systems.

The increasing complexity of battery applications and their operational environments has led to the development of various modeling approaches, including some approaches that rely on an equivalent circuit model (ECM). ECMs may represent battery behavior using electrical components, such as resistors and capacitors, to simulate the electrochemical processes within the battery. These models may provide a simplified representation of battery dynamics in an effort to perform calculations of battery states and performance characteristics. While ECMs provide a simplified representation of battery dynamics, they often struggle to accurately capture the complex physical behaviors and electrochemical processes occurring within battery cells during real-world operation, particularly under varying conditions or as the battery ages. Consequently, the estimations generated by ECMs often do not have sufficient accuracy or reliability to be used in electric vehicle systems and/or other battery-powered systems.

Another potential approach to estimate or measure parameters of batteries may be to apply a pseudo-two-dimensional (P2D) electrochemical model. However, traditional P2D models have several disadvantages. These models typically involve solving partial differential equations (PDEs), which often rely on finite element methods, leading to slower simulation speeds. Moreover, these models are computationally intensive, often requiring significant processing power and time to estimate parameters, which may limit their applicability in real-time battery management systems.

The background description provided herein is for the purpose of generally presenting context of the disclosure. The materials described in this section are not prior art to the claims in this application and are not admitted to be prior art, or suggestions of the prior art, by inclusion in this section.

### SUMMARY

The present disclosure relates to systems, methods, apparatuses, computer program products, and techniques for estimating battery parameters. In certain embodiments, a battery analysis system utilizes a combination of reduced-order and full-order electrochemical models, along with data preprocessing algorithms and machine learning-based optimization techniques, to rapidly and accurately estimate various battery parameters for one or more battery cells. In certain embodiments, the battery analysis system can execute a multi-stage estimation approach, initially leveraging a shallow estimation function to quickly narrow down parameter ranges, followed by a deep estimation function for final refinement if higher accuracy is desired. This combined approach allows for efficient parameter estimation across various operating scenarios, balancing both speed and precision considerations, and enables real-time parameter estimates for battery management systems in applications such as electric vehicles.

In certain embodiments, a shallow estimation function may initially be executed that utilizes one or more reduced-order electrochemical models to perform rapid battery parameter estimation. If further accuracy is desired, a deep estimation function can subsequently be employed to further hone the accuracy of the battery parameters. In scenarios where the deep estimation function is utilized to refine the accuracy of the battery parameters, the estimates output by the shallow estimation function can be leveraged to reduce the parameter ranges for the deep estimation function, significantly reducing the convergence time and computational resources for generating final estimations for the battery parameter estimations.

In certain embodiments, one or more preprocessing functions also may be executed on input data provided to the shallow estimation function and/or deep estimation function to further improve efficiency and reduce the computation times for generate the battery parameter estimates. In some examples, the battery analysis system may receive raw current data and a preprocessing function can be executed to reduce the frequency and amplitude of the current data. In some embodiments, the preprocessing function may apply Gaussian filtering, Kalman filtering, and/or specially designed convolution kernels to reduce the frequency and amplitude of the input current data.

During preprocessing operations, the one or more preprocessing functions also may be used to select an optimal reduction metric that quantifies the degree of preprocessing performed on the input current data. In certain embodiments, the preprocessing function may execute an evaluation process to identify an optimized reduction metric that maximizes the reduction in frequency and amplitude of the current data to improve simulation efficiency, while also ensuring sufficient accuracy of model simulations. This selection process for identifying the reduction metric may involve comparing simulated terminal voltage profiles generated using preprocessed data against benchmark voltage profiles. The reduction metric may be iteratively adjusted and re-evaluated until an acceptable balance between computational efficiency and simulation accuracy is achieved. By identifying and applying an optimal reduction metric, the preprocessing function can significantly reduce the computational requirements typically associated with processing high-frequency current data, enabling more efficient battery parameter estimation with high accuracy.

In certain embodiments, the shallow and deep estimation functions may utilize improved optimization functions in combination with the electrochemical models to generate the battery parameter estimates. In some examples, these optimization functions may employ one or more machine learning-based pruner/sampler algorithms designed to quickly narrow down the selection space for each battery parameter being estimated. In certain embodiments, preprocessing functions executed on the input current data can enhance the efficiency of the electrochemical models and/or optimization functions by reducing the computational complexity of the input data, allowing for faster convergence on parameter estimations. Additionally, during the deep estimation stage, the estimates from the shallow estimation stage may be utilized to narrow the selection space for the optimization function used in the deep estimation process, significantly reducing the number of iterations to converge on final parameter values.

The battery analysis system can be utilized to estimate various types of battery parameters. These parameters may include degradation parameters, thermal parameters, battery model parameters, and state-of-health (SOH) parameters. In certain embodiments, the battery analysis system may initially estimate the model parameters using one or more of the techniques described in this disclosure, and these model parameters may then be utilized as inputs or constraints in subsequent estimations of degradation, thermal, and/or SOH parameters.

In certain embodiments, the battery analysis system can be configured to generate or determine a diagnostic assessment for each battery cell that is analyzed by the system. The diagnostic assessments for battery cells can be determined or generated based, at least in part, on one or more of the battery parameter estimations obtained or derived according to the techniques described in this disclosure. In some examples, when one or more battery parameters align with expected values or ranges, the diagnostic assessment may indicate that a battery cell is operating under normal conditions and/or may provide a positive assessment. Conversely, when one or more battery parameters deviate from expected values or ranges, the diagnostic assessment may indicate that a battery cell is operating under abnormal conditions and/or may provide a negative assessment.

In certain embodiments, the battery analysis system (or a corresponding battery management system in communication therewith) can be configured to execute or implement one or more mitigation functions based, at least in part, on the diagnostic assessment for one or more battery cells. For example, one or more mitigation functions may be executed or carried out in response to a diagnostic assessment indicating a negative assessment or indicating abnormal operating conditions.

The types of mitigation functions executed can vary and, in some cases, may depend upon the particular battery parameters identified as deviating from expected operating conditions. In some examples, the mitigation functions may adjust the operating parameters and/or settings of battery cells corresponding to a negative diagnostic assessment. This could involve modifying voltage, current, resistance, temperature, thermal management, and/or other operational settings to address the identified issues. In further examples, the system also may implement isolation procedures for one or more battery cells in response to detecting a negative diagnostic assessment corresponding to those cells. In further examples, the mitigation functions may include transmitting alerts or notifications when negative diagnostic assessments are detected for one or more battery cells. These alerts could be sent to the vehicle or device containing the affected battery cells, or to a technical service provider, and can identify details related to the negative assessment and/or indicate that the one or more battery cells should be replaced. The battery analysis system may execute or implement other types of mitigation functions in response to the derived diagnostic assessments as well, aiming to address identified issues and optimize overall battery performance and longevity.

The battery analysis system can be deployed in various environments and configurations. In certain embodiments, the system may be hosted on servers or in cloud-based environments, allowing for scalable processing and real-time parameter estimations for multiple devices simultaneously. This approach may enable battery analysis system to rapidly compute battery estimates by leveraging greater computational resources in performing the electrochemical simulations, while continuously refining the optimization functions using a wider range of input data derived across multiple battery-powered devices. Additionally, or alternatively, the battery analysis system can be directly integrated into battery-powered devices including, but not limited to, electric vehicles. This on-device implementation may provide immediate, localized parameter estimations without relying on network connectivity, potentially reducing latency attributable to network connectivity, and enhancing data security maintain the data locally on the battery-powered devices. Additionally, or alternatively, a hybrid approach combining both server-based and on-device components may be utilized to leverage the advantages of both configurations.

In certain embodiments, a method is provided for estimating one or more battery parameters that includes: receiving, by a battery analysis system, current data corresponding to a battery cell; generating, by a preprocessing function of the battery analysis system, preprocessed current data based on the current data, the preprocessed current data having a reduced frequency and a reduced amplitude relative to the current data; receiving, by a shallow estimation function of the battery analysis system, the preprocessed current data; executing the shallow estimation function to estimate one or more battery parameters corresponding to the battery cell, at least in part, by applying the preprocessed current data as an input to a simulation executed by a reduced-order electrochemical model; and determining a diagnostic assessment corresponding to the battery cell based, at least in part, on the one or more battery parameters.

In certain embodiments, the shallow estimation function can include an optimization function that works in conjunction with the reduced-order electrochemical model to estimate one or more battery parameters. Generating the pre-processed current data prior to execution of the shallow estimation function can operate to narrow down a parameter range utilized by the optimization function in estimating the one or more battery parameters.

In certain embodiments, the method may further comprise the steps of: determining if the one or more battery parameters estimated using the shallow estimation function are sufficiently accurate; and in response to determining that the one or more battery parameters are not sufficiently accurate, executing a deep estimation function that utilizes a full-order electrochemical model to refine the one or more battery parameters corresponding to the battery cell.

In certain embodiments, the one or more battery parameters estimated by the shallow estimation function can be applied to narrow a parameter range for the deep estimation function.

In certain embodiments, the method further comprises: receiving reference voltage data comprising charging/discharging data derived from one or more battery-powered devices; determining a benchmark terminal voltage profile based, at least in part, on the reference voltage data; generating, using the reduced-order electrochemical model, a simulated terminal voltage profile based on the preprocessed current data; and comparing the simulated terminal voltage profile with the benchmark terminal voltage profile to assess a sufficiency of the preprocessed current data.

In certain embodiments, the preprocessed current data can be generated according to a reduction metric that quantifies a degree to which a frequency and an amplitude of the current data is reduced and, in response to determining that the difference between the simulated terminal voltage profile and the benchmark terminal voltage profile satisfies an error threshold, the preprocessed current data is determined to be acceptable for usage in estimating the one or more battery parameters corresponding to the battery cell.

In certain embodiments, the preprocessed current data can be generated according to a first reduction metric that quantifies a degree to which a frequency and an amplitude of the current data is reduced and, in response to determining that the difference between the simulated terminal voltage profile and the benchmark terminal voltage profile does not satisfy an error threshold, new preprocessed current data is generated according to a second reduction metric that reduces the frequency and the amplitude of the current data to a lesser extent relative to the first reduction metric.

In certain embodiments, the preprocessed current data can be continuously or iteratively refined according to a new reduction metric until the difference between the simulated terminal voltage profile and the benchmark terminal voltage profile satisfies the error threshold.

In certain embodiments, the battery analysis system can be configured to estimate the one or more battery parameters for one or more battery cells included in an electric vehicle.

In certain embodiments, the battery analysis system can be integrated directly into the electric vehicle or can be integrated into a cloud environment that is in communication with the electric vehicle over a network.

In certain embodiments, the one or more battery parameters include at least one of: a degradation parameter corresponding to the battery cell; a thermal parameter corresponding to the battery cell; a model parameter corresponding to the battery cell; or a state-of-health (SOH) parameter corresponding to the battery cell.

In certain embodiments, a system is provided for estimating one or more battery parameters comprising one or more processing devices and one or more non-transitory storage devices storing computing instructions. Execution of the instructions by the one or more processors can cause the one or more processors to perform operations comprising: receiving, by a battery analysis system, current data corresponding to a battery cell; generating, by a preprocessing function of the battery analysis system, preprocessed current data based on the current data, the preprocessed current data having a reduced frequency and a reduced amplitude relative to the current data; receiving, by a shallow estimation function of the battery analysis system, the preprocessed current data; executing the shallow estimation function to estimate one or more battery parameters corresponding to the battery cell, at least in part, by applying the preprocessed current data as an input to a simulation executed by a reduced-order electrochemical model; and determining a diagnostic assessment corresponding to the battery cell based, at least in part, on the one or more battery parameters.

In certain embodiments, the shallow estimation function can comprise an optimization function that works in conjunction with the reduced-order electrochemical model to estimate one or more battery parameters, and generating the preprocessed current data prior to execution of the shallow estimation function can operate to narrow down a parameter range utilized by the optimization function in estimating the one or more battery parameters.

In certain embodiments, execution of the computing instructions can further cause the one or more processors to perform operations comprising: determining if the one or more battery parameters estimated using the shallow estimation function are sufficiently accurate; and in response to determining that the one or more battery parameters are not sufficiently accurate, executing a deep estimation function that utilizes a full-order electrochemical model to refine the one or more battery parameters corresponding to the battery cell.

In certain embodiments, the one or more battery parameters estimated by the shallow estimation function can be applied to narrow a parameter range for the deep estimation function.

In certain embodiments, execution of the computing instructions can further cause the one or more processors to perform operations comprising: receiving reference voltage data comprising charging/discharging data derived from one or more battery-powered devices; determining a benchmark terminal voltage profile based, at least in part, on the reference voltage data; generating, using the reduced-order electrochemical model, a simulated terminal voltage profile based on the preprocessed current data; and comparing the simulated terminal voltage profile with the benchmark terminal voltage profile to assess a sufficiency of the preprocessed current data.

In certain embodiments, the preprocessed current data can be generated according to a reduction metric that quantifies a degree to which a frequency and an amplitude of the current data is reduced, and the battery analysis can be configured to evaluate the preprocessed current data. In response to determining that the difference between the simulated terminal voltage profile and the benchmark terminal voltage profile satisfies an error threshold, the preprocessed current data generated according to the reduction metric may be determined to be acceptable for usage in estimating the one or more battery parameters corresponding to the battery cell. In response to determining that the difference between the simulated terminal voltage profile and the benchmark terminal voltage profile does not satisfy an error threshold, the preprocessed current data can be iteratively refined according to a new reduction metric until the difference between the simulated terminal voltage profile and the benchmark terminal voltage profile satisfies the error threshold.

In certain embodiments, the battery analysis system is configured to estimate the one or more battery parameters for one or more battery cells included in an electric vehicle, and the battery analysis system is integrated directly into the electric vehicle or is integrated into a cloud environment that is in communication with the electric vehicle.

In certain embodiments, a method is provided for estimating one or more battery parameters comprising: receiving, by a shallow estimation function, the current data; executing the shallow estimation function to estimate one or more battery parameters corresponding to the battery cell, at least in part, by applying the current data as an input to a simulation executed by a reduced-order electrochemical model; receiving, by a deep estimation function of the battery analysis system, the one or more battery parameters estimated using the shallow estimation function; executing the deep estimation function to refine the one or more battery parameters corresponding to the battery cell, wherein the deep estimation function utilizes a full-order electrochemical model to refine the one or more battery parameters corresponding to the battery cell, and the one or more battery parameters estimated by the shallow estimation function are applied to narrow a parameter range for the deep estimation function; and determining a diagnostic assessment corresponding to the battery cell based, at least in part, on the one or more battery parameters.

In certain embodiments, the current data can be preprocessed by the battery analysis system prior to execution of the shallow estimation function or the deep estimation function to reduce a frequency and an amplitude of the current data.

In certain embodiments, the current data can be preprocessed according to a reduction metric that quantifies a degree to which a frequency and an amplitude of the current data is reduced, and the current data can be iteratively refined according to a new reduction metric until an error threshold is satisfied.

The battery analysis techniques described in this disclosure address several technical challenges in technologies related to battery parameter estimation and management including, but not limited to, shortcomings of traditional equivalent circuit models (ECMs) and traditional pseudo-two-dimensional (P2D) electrochemical models. ECMs often struggle to accurately capture complex physical behaviors and electrochemical processes within battery cells, particularly under varying conditions or as batteries age, leading to unreliable estimations for electric vehicle systems and other battery-powered devices. Conventional pseudo-two-dimensional (P2D) electrochemical models, while more accurate, typically involve solving partial differential equations using computationally intensive finite element methods, resulting in slower simulation speeds and limited applicability in real-time battery management systems.

The techniques described herein provide technical solutions for overcoming these and other limitations in traditional battery parameter estimation and management technologies. For example, certain approaches described herein implement a multi-stage parameter evaluation approach that combines reduced-order and/or full-order electrochemical models with advanced data preprocessing and machine learning-based optimization techniques, which can facilitate rapid and accurate estimation of various battery parameters, while significantly reducing computational requirements. Additionally, the system's ability to quickly narrow down parameter ranges and adapt to different operational scenarios allows for efficient real-time parameter estimation across diverse applications, addressing the growing need for sophisticated battery management solutions in increasingly complex battery configurations and operational environments.

In many embodiments, the techniques described herein can be used continuously at a scale that cannot be reasonably performed using manual techniques or the human mind. For example, in some embodiments, the battery analysis system may continuously process large volumes of high-frequency current and/or voltage data from multiple battery cells simultaneously, executing hundreds or thousands of electrochemical model simulations per second. Additionally, in many scenarios, these simulations may involve solving complex systems of differential equations that model intricate electrochemical processes occurring within the battery cells. Additionally, the machine learning-based optimization functions may concurrently explore vast multi-dimensional parameter spaces, iteratively refining estimates based on simulation results. This combination of parallel simulations and parameter optimization enables the system to rapidly estimate and update battery parameters and, in some cases, to be deployed in real-time battery systems. The scale and quantity of these computations far exceed what could be achieved through manual analysis or human cognitive processes alone.

Additionally, the techniques described herein can solve a technical problem that arises only within the realm of computing, as machine-learning and simulation models do not exist outside the realm of computer systems.

The battery analysis system embodies a practical application by providing tangible improvements to battery management and performance in real-world devices and systems. In certain embodiments, by rapidly and accurately estimating battery parameters, the system can facilitate more precise control and optimization of battery operation in electric vehicles, consumer electronics, and/or battery-operated devices. This can provide concrete benefits such as extended battery lifespan, improved charging efficiency, and enhanced safety through early detection of potential issues. For example, in electric vehicles, real-time parameter estimates can facilitate dynamic adjustment of charging and discharging strategies, optimizing range and reducing degradation. By addressing various challenges in battery management with the technical solutions described herein, the battery analysis techniques provide specific, real-world advancements in battery technology applications.

### BRIEF DESCRIPTION OF DRAWINGS

The patent or application file contains at least one drawing executed in color. Copies of this patent or patent application publication with color drawing(s) will be provided by the Office, upon request and payment of the necessary fee.

Non-limiting and non-exhaustive examples are described with reference to the following figures. To facilitate further description of the embodiments, the following drawings are provided, in which like references are intended to refer to like or corresponding parts.

FIG. 1A is a diagram of an exemplary system according to certain embodiments.

FIG. 1B is a block diagram illustrating exemplary features of a battery analysis system according to certain embodiments.

FIG. 2A is a flow chart illustrating an exemplary method according to certain embodiments.

FIG. 2B is a flow chart illustrating another exemplary method according to certain embodiments.

FIG. 3A is a graph illustrating a comparison of current data before and after preprocessing based on a first reduction metric according to certain embodiments.

FIG. 3B is a graph illustrating a comparison of current data before and after preprocessing based on a second reduction metric according to certain embodiments.

FIG. 3C is a graph illustrating a comparison of current data before and after preprocessing based on a third reduction metric according to certain embodiments.

FIG. 3D is a graph illustrating a comparison of current data before and after preprocessing based on a fourth reduction metric according to certain embodiments.

FIG. 3E is a graph illustrating a comparison of current data before and after preprocessing based on a fifth reduction metric according to certain embodiments.

FIG. 3F is a graph illustrating a comparison of current data before and after preprocessing based on a sixth reduction metric according to certain embodiments.

FIG. 4A is a graph illustrating exemplary raw current data measured for a battery cell for two cycles according to certain embodiments.

FIG. 4B is a graph illustrating exemplary terminal voltage data measured for a battery cell for two cycles according to certain embodiments.

FIG. 4C is a graph illustrating exemplary raw current data measured for a battery cell according to certain embodiments.

FIG. 4D is a graph illustrating exemplary terminal voltage data measured for a battery cell according to certain embodiments.

FIG. 5A is a graph illustrating exemplary raw current data measured for a battery cell for three cycles according to certain embodiments.

FIG. 5B is a graph illustrating exemplary terminal voltage data measured for a battery cell for three cycles according to certain embodiments.

FIG. 5C is a graph illustrating a comparison of a simulated terminal voltage profile for an estimated model parameter and a benchmark terminal voltage profile according to certain embodiments.

FIG. 6A is a graph illustrating a narrowed selection space for a first battery parameter according to certain embodiments.

FIG. 6B is a graph illustrating a narrowed selection space for a second battery parameter according to certain embodiments.

FIG. 6C is a graph illustrating a narrowed selection space for a third battery parameter according to certain embodiments.

FIG. 6D is a graph illustrating a narrowed selection space for a first battery parameter according to certain embodiments.

FIG. 7A is a graph illustrating a comparison of a simulated terminal voltage profile with a benchmark terminal voltage profile at a first checking point according to certain embodiments.

FIG. 7B is a graph illustrating a comparison of a simulated terminal voltage profile with a benchmark terminal voltage profile at a second checking point according to certain embodiments.

FIG. 7C is a graph illustrating a comparison of a simulated terminal voltage profile with a benchmark terminal voltage profile at a third checking point according to certain embodiments.

FIG. 7D is a graph illustrating a comparison of a simulated terminal voltage profile with a benchmark terminal voltage profile at a fourth checking point according to certain embodiments.

FIG. 7E is a graph illustrating a comparison of a simulated terminal voltage profile with a benchmark terminal voltage profile at a fifth checking point according to certain embodiments.

FIG. 7F is a graph illustrating a comparison of a simulated terminal voltage profile with a benchmark terminal voltage profile at a sixth checking point according to certain embodiments.

FIG. 7G is a graph illustrating a comparison of a simulated terminal voltage profile with a benchmark terminal voltage profile at a seventh checking point according to certain embodiments.

FIG. 7H is a graph illustrating a comparison of a simulated terminal voltage profile with a benchmark terminal voltage profile at an eighth checking point according to certain embodiments.

FIG. 7I is a graph illustrating a comparison of a simulated terminal voltage profile with a benchmark terminal voltage profile at a ninth checking point according to certain embodiments.

FIG. 7J is a graph illustrating a comparison of a simulated terminal voltage profile with a benchmark terminal voltage profile at a tenth checking point according to certain embodiments.

FIG. 8A is a graph illustrating an exemplary changing pattern of a battery model parameter during operation according to certain embodiments.

FIG. 8B is a graph illustrating another exemplary changing pattern of a battery model parameter during operation according to certain embodiments.

FIG. 8C is a graph illustrating another exemplary changing pattern of a battery model parameter during operation according to certain embodiments.

FIG. 8D is a graph illustrating another exemplary changing pattern of a battery model parameter during operation according to certain embodiments.

FIG. 8E is a graph illustrating another exemplary changing pattern of a battery model parameter during operation according to certain embodiments.

FIG. 8F is a graph illustrating another exemplary changing pattern of a battery model parameter during operation according to certain embodiments.

FIG. 9A is a graph illustrating exemplary current data according to certain embodiments.

FIG. 9B is a graph illustrating an exemplary benchmark terminal voltage profile according to certain embodiments.

FIG. 9C is a graph illustrating a comparison of a benchmark terminal voltage profile with a simulated terminal voltage profile according to certain embodiments.

FIG. 9D is a graph illustrating another comparison of a benchmark terminal voltage profile with a simulated terminal voltage profile according to certain embodiments.

FIG. 10A is a network diagram illustrating an exemplary system that hosts a battery analysis system in a server or cloud-based environment according to certain embodiments.

FIG. 10B is a block diagram illustrating a battery analysis system integrated into a battery-powered device according to certain embodiments.

FIG. 10C is an illustration of a battery analysis system integrated into a vehicle according to certain embodiments.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein.

The terms “left,” “right,” “front,” “rear,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the apparatus, methods, and/or articles of manufacture described herein are, for example, capable of operation in other orientations than those illustrated or otherwise described herein.

As used herein, “approximately” can, in some embodiments, mean within plus or minus ten percent of the stated value. In other embodiments, “approximately” can mean within plus or minus five percent of the stated value. In further embodiments, “approximately” can mean within plus or minus three percent of the stated value. In yet other embodiments, “approximately” can mean within plus or minus one percent of the stated value.

Certain data or functions may be described as “real-time,” “near real-time,” or “substantially real-time” within this disclosure. Any of these terms can refer to data or functions that are processed with a humanly imperceptible delay or minimal humanly perceptible delay. Alternatively, these terms can refer to data or functions that are processed within a specific time interval (e.g., in the order of milliseconds).

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

The embodiments described in this disclosure can be combined in various ways. Any aspect or feature that is described for one embodiment can be incorporated to any other embodiment mentioned in this disclosure. Moreover, any of the embodiments described herein may be hardware-based, may be software-based, or, preferably, may comprise a mixture of both hardware and software elements. Thus, while the description herein may describe certain embodiments, features, or components as being implemented in software or hardware, it should be recognized that any embodiment, feature and/or component referenced in this disclosure can be implemented in hardware and/or software.

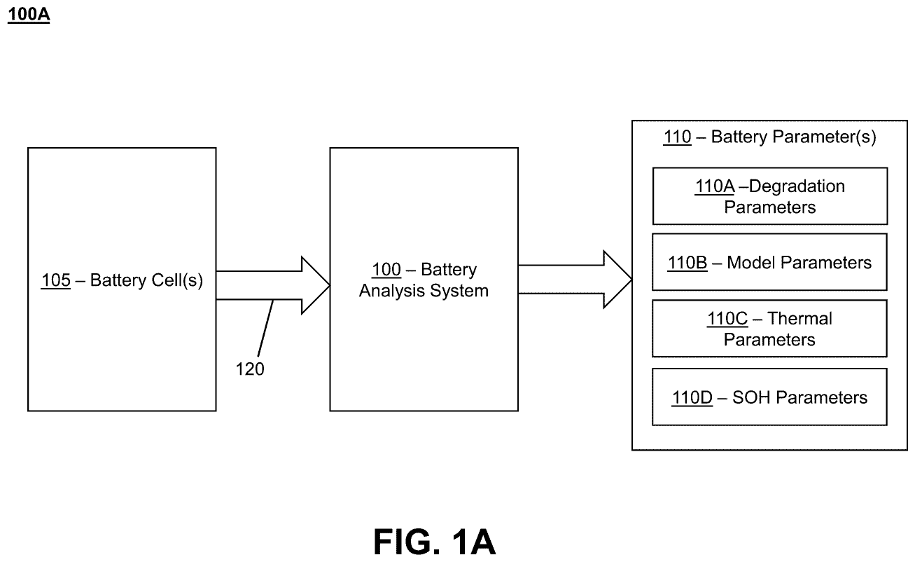

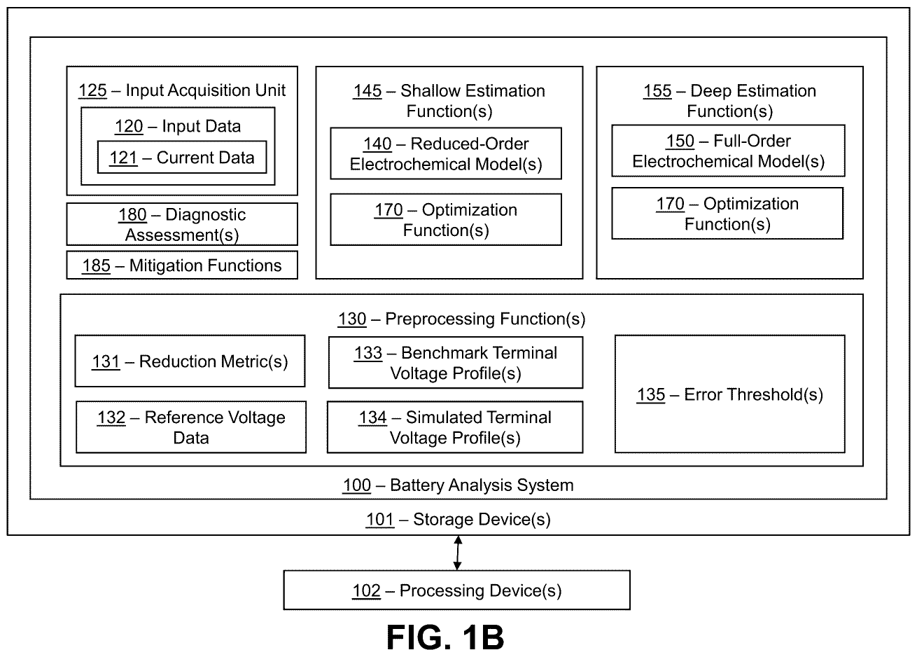

FIG. 1A illustrates an exemplary system 100A for estimating battery parameters. The system comprises one or more battery cells 105 and a battery analysis system 100 that measures or estimates one or more battery parameters 110 corresponding to the one or more battery cells 105.

In certain embodiments, the battery analysis system 100 can be configured to estimate or measure one or more battery parameters 110 for each of the battery cells 105. The battery analysis system 100 can estimate or measure the one or more battery parameters 110 using any techniques described in this disclosure. In certain embodiments, the battery analysis system 100 can estimate one or more battery parameters 110 with increased speed and efficiency utilizing a combination of reduced-order electrochemical models, data preprocessing algorithms, and machine learning-based optimization techniques, which operate to quickly narrow down parameter ranges before applying full electrochemical models for final refinement. Further details of these parameter estimation techniques are described below.

The battery analysis system 100 can be implemented in software, hardware, or a combination thereof. In some examples, the battery analysis system 100 can comprise a software-based model or system comprising computer instructions or logic that implements some or all of the parameter estimation techniques described herein. The computer instructions or logic may be stored on one or more storage devices and executed by one or more processing devices. Additionally, or alternatively, the battery analysis system 100 can be comprise one or more application-specific integrated circuits (ASICs), one or more field-programmable gate arrays (FPGAs), and/or other hardware components designed to perform some or all of the parameter estimation techniques described herein.

The battery analysis system 100 can be configured to estimate or measure the battery parameters 110 for any type of battery cell 105. In some examples, the battery cells 105 can correspond to lithium-ion battery cells. Additionally, or alternatively, the battery cells 105 can correspond to lithium-metal battery cells, sodium-ion battery cells, semi-solid-state battery cells, all-solid-state battery cells, zinc-ion battery cells, lithium-sulfur battery cells, flow battery cells, proton-exchange membrane fuel cells, and/or other types of electrochemical battery cells.

The battery parameter estimation techniques described herein can be performed on any number of battery cells 105. In certain embodiments, the parameter estimation techniques can be applied to estimate or measure battery parameters 110 for a plurality of battery cells 105 (e.g., two or more battery cells 105 connected in series or in parallel). In other embodiments, the battery parameter estimation techniques can be applied to estimate or measure battery parameters 110 for a single battery cell 105.

In certain embodiments, the battery analysis system 100 receives input data 120 from each of the battery cells 105, which is utilized by the battery analysis system 100 to estimate or measure one or more battery parameters 110 for each of the battery cells 105. In some examples, the input data 120 may comprise current data 121 indicating or measuring current values corresponding to each of the battery cells 105. In certain embodiments, the input data 120 may additionally, or alternatively, include data indicating or measuring other attributes of the battery cells 105 (e.g., such as the voltage, resistance, and/or other criteria or conditions for each of the battery cells 105).

The types of battery parameters 110 estimated or measured by the battery analysis system 100 can vary. In certain embodiments, the battery parameters 110 estimated or measured by the battery analysis system 100 can include one or more degradation parameters 110A, one or more model parameters 110B, one or more thermal parameters 110C, and/or one or more SOH (state-of-health) parameters 110D. The battery analysis system 100 also can be configured to estimate or measure other types of battery parameters 110 including, but not limited to, any other parameters mentioned in this disclosure.

The degradation parameters 110A may generally include any metrics, measurements, and/or indicators that can be utilized to characterize the deterioration or aging of the battery cells 105 or their performance over time and/or during usage. In certain embodiments, the degradation parameters 110A may indicate the reaction rates of anode and cathode SEI (solid-electrolyte interphase) layer evolution, lithium plating, particle dissolution, and/or electrolyte decomposition. Additionally, or alternatively, the degradation parameters 110A may indicate the anode SEI formation rate, cathode SEI formation rate, cathode film formation rate, lithium-plating rate, electrolyte decomposition rate, transitional metal dissolution rate, film resistance, capacity fade rate, internal resistance increase, self-discharge rate, electrolyte decomposition rates, electrode material dissolution rates, and/or cycling efficiency loss for each of the battery cells 105. The battery analysis system 100 may estimate other types of degradation parameters 110A as well.

The model parameters 110B may generally include any variables, parameters, settings, and/or other criteria that are utilized by electrochemical models, such as the reduced-order and full-order electrochemical models described herein, to conduct simulations and/or estimate parameters of battery cells 105. In general, the model parameters 110B may include variables, criteria or settings associated with the physical and/or chemical properties of the battery cells 105, and/or associated with the behavior and performance of the battery cells 105. In some examples, the model parameters 110B may indicate, inter alia, the volume fraction of solid and liquid phases, electrode particle radius, tortuosity of electrodes and electrolyte, and/or kinetic reaction rates of active materials. The model parameters 110B may additionally, or alternatively, indicate the initial state of charge (SOC) of the cathode and anode, the initial salt concentration in the electrolyte, the kinetic reaction rate of the particle surface, and/or other adjustment factors that modify variables in an electrochemical model affected by specific mechanisms, such as changes in active surface area due to electrode volume changes and particle compaction gaps. The battery analysis system 100 may estimate other types of model parameters 110B as well.

The thermal parameters 110C may generally include any metrics, measurements, and/or indicators associated with the thermal properties, behavior and/or performance of the battery cells 105. The thermal parameters 110C may indicate the specific heat and thermal conductivity of electrodes and electrolytes associated with the battery cells 105, as well as the activation energy of diffusivity and conductivity of electrodes and electrolytes. Additionally, or alternatively, the thermal parameters 110C also indicate heat generation rates during charging and discharging processes, as well as heat transfer coefficients between the battery and its surrounding environment. The battery analysis system 100 may estimate other types of thermal parameters 110C as well.

The battery SOH parameters 110D may generally include metrics and indicators that reflect the health, condition and/or performance capability of the battery cells 105 relative to their initial or ideal state and/or the aging of the battery cells 105. In some examples, the battery SOH parameters 110D may be derived, at least in part, from an evaluation of the degradation parameters 110A over time.

As described throughout this disclosure, the battery analysis system 100 can utilize improved techniques for estimating the aforementioned battery parameters 110 and/or other types of battery parameters.

FIG. 1B illustrates exemplary features, functions, and/or components of the battery analysis system 100 according to certain embodiments. The features, functions, and/or components of the battery analysis system 100 may be illustrated or described in certain portions of this disclosure as separate or distinct components for clarity and ease of explanation. However, it should be understood that these features, functions, and/or components can be combined and/or integrated in various ways.

The battery analysis system 100 can be stored on one or more storage devices 101 that are in communication with one or more processing devices 102.

The one or more storage devices 101 may include (i) non-volatile memory, such as, for example, read only memory (ROM) and/or (ii) volatile memory, such as, for example, random access memory (RAM). The non-volatile memory may be removable and/or non-removable non-volatile memory. RAM may include dynamic RAM (DRAM), static RAM (SRAM), etc. Further, ROM may include mask-programmed ROM, programmable ROM (PROM), one-time programmable ROM (OTP), erasable programmable read-only memory (EPROM), electrically erasable programmable ROM (EEPROM) (e.g., electrically alterable ROM (EAROM) and/or flash memory), etc. In certain embodiments, the one or more storage devices 101 include physical, non-transitory mediums.

The one or more processing devices 102 may include one or more central processing units (CPUs), one or more microprocessors, one or more microcontrollers, one or more controllers, one or more complex instruction set computing (CISC) microprocessors, one or more reduced instruction set computing (RISC) microprocessors, one or more very long instruction word (VLIW) microprocessors, one or more graphics processor units (GPU), one or more digital signal processors, one or more application specific integrated circuits (ASICs), and/or any other type of processor or processing circuit capable of performing desired functions.

The one or more storage devices 101 can store data and instructions associated with implementing any or all of the functionalities of the battery analysis system 100 and its corresponding components (e.g., including any instructions associated with the input acquisition unit 125, preprocessing functions 130, shallow estimation functions 145, deep estimation functions 155, optimization functions 170, and/or any other functionalities associated with the battery analysis system 100). The one or more processing devices 102 can be configured to execute the instructions stored on the one or more storage devices 101. Exemplary configurations for each of these components are described in further detail below.

The battery analysis system 100 comprises an input acquisition unit 125 that is configured to receive, access, and/or store input data 120 corresponding to each of the battery cells 105. In certain embodiments, the input data 120 may comprise current data 121 indicating the current values or measurements for each of the battery cells 105. In certain embodiments, the current data 121 may be measured, calculated, or estimated using a hardware-based and/or software-based current measurement unit and, in some cases, may include one or more current sensors and/or one or more shunt resistors. The current measurement unit may be part of the battery analysis system 100 (e.g., part of the input acquisition unit 125) and/or may be an external component that is in communication with the battery analysis system 100.

The battery analysis system 100 may execute a shallow estimation function 145 (also referred to as a “fast estimation function” or “reduced-order estimation function” herein), a deep estimation function 155 (also referred to as a “full-order estimation function” herein), or a combination thereof to estimate battery parameters 110 for battery cells 105 based, at least in part, on the input data 120 (e.g. current data 121) obtained from the battery cells 105. The shallow estimation function 145 may utilize one or more reduced-order electrochemical models 140 to estimate the battery parameters 110 for battery cells 105, and the deep estimation function 155 may utilize one or more full-order electrochemical models 150 to estimate the battery parameters 110 for battery cells 105. In certain embodiments, the shallow estimation function 145 and the deep estimation function 155 each may include and execute one or more optimization functions 170, which operate in combination with the electrochemical models to estimate the battery parameters 110 for the battery cells 105.

In certain embodiments, each full-order electrochemical model 150 may include a detailed physics-based model (e.g., a pseudo two-dimensional or P2D model) that simulates the electrochemical processes occurring within battery cells 105. In some embodiments, these models may utilize partial differential equations (PDEs) to represent phenomena such as charge transfer, mass transport, and reaction kinetics across multiple spatial and temporal scales. Additionally, the full-order electrochemical models 150 also may utilize finite element methods and/or other numerical techniques to solve these equations, providing high-fidelity representations of battery behavior. The full-order electrochemical models 150 may account for various physical and chemical parameters of the battery cells 105, including electrode thickness, particle size distribution, electrolyte properties, and reaction rates. While these models may offer high accuracy, they typically consume significant computational resources and have relatively long simulation times.

In general, each reduced-order electrochemical model 140 may include a more simplified or streamlined model for simulating the electrochemical processes occurring within the battery cells 105 in comparison to a full-order electrochemical model 150. For example, when compared to the full-order electrochemical model 150, the reduced-order electrochemical model 140 may estimate battery parameters 110 more rapidly and may have a lower input database size requirement. In some embodiments, a reduced-order electrochemical model 140 can represent a single particle model that has been modified and/or optimized to reduce computation resources and/or simulation times. In certain embodiments, the reduced-order electrochemical model 140 may be constructed using order reduction techniques that serve to decrease the number of state variables and/or equations that are solved during battery simulations. In some instances, the reduced-order electrochemical model 140 may utilize approximations and assumptions to reduce computational complexity, while maintaining high accuracy for specific operating conditions. The reduced-order electrochemical model 140 may be calibrated and validated against experimental data and/or higher-fidelity models to ensure its predictions remain sufficiently accurate within its intended operating range.

In certain embodiments, the reduced-order electrochemical model 140 may utilize certain physical and chemical parameters of the battery cells 105, but with simplified mathematical formulations compared to full-order electrochemical models 150. In some embodiments, the reduced-order electrochemical model 140 can be subjected to a detailed calibration procedure that obviates the need for solving PDEs, yet enables the reduced-order electrochemical model 140 to accurately simulate electrochemical performance of battery cells 105 having certain C-rate profiles (e.g., higher C-rate profiles and/or C-rates of 2.5 C and above). The more streamlined nature of the reduced-order electrochemical model 140 can allow for faster computation times, making them particularly suitable for real-time applications and/or rapid parameter estimation processes.

As explained throughout this disclosure, the battery analysis system 100 may estimate battery parameters 110 using a multi-stage approach that leverages the strengths and advantages of both of the aforementioned electrochemical model types (i.e., reduced-order and full-order models). In some examples, the battery analysis system 100 may initially execute a shallow estimation function 145 that relies on at least one reduced-order electrochemical model 140 to quickly narrow down parameter ranges for desired battery parameters 110 (taking advantage of its faster computation times and reduced computational complexity) and, if further accuracy is desired, subsequently execute a deep estimation function 155 that relies on at least one full-order electrochemical model 150 for final refinement of the battery parameters 110 (and benefiting from its higher accuracy). In the event that the deep estimation function 155 is applied to hone the accuracy of the battery parameters 110, the battery parameter estimates output by the shallow estimation function 145 can be utilized to narrow the parameter selection space for the deep estimation function 155, thereby significantly reducing the computational resources and simulation times for performing the deep estimation function 155. This combined approach may allow the system to efficiently estimate parameters across various operating scenarios, while balancing both speed and precision considerations in estimating the battery parameters 110. Additionally, in some embodiments, these techniques can enable parameter estimates to be generated for real-time systems and applications.

In certain embodiments, the electrochemical models (both the reduced-order electrochemical model 140 and the full-order electrochemical model 150) can include, utilize, and/or communicate with one or more optimization functions 170 to estimate the battery parameters 110. The design and/or configuration of the one or more optimization functions 170 can vary. In certain embodiments, each optimization function 170 may correspond to a machine-learning (ML) model that is pre-trained for battery parameter optimization. In some examples, the machine learning model may execute a pruner/sampler algorithm that is designed to quickly narrow down the selection space for each battery parameter being estimated by sampling from the parameter ranges and pruning suboptimal solutions. Additionally, the ML model may iteratively refine the battery parameter estimates, allowing for rapid convergence to optimal values and significantly reducing the computational time and resources for estimating the battery parameters. In some embodiments, the techniques described herein can be applied to narrow down parameter ranges used by the optimization function 170 in estimating each of the battery parameters 110, thereby significantly reducing the number of iterations and/or computational time of the optimization function 170 in deriving optimized values for the battery parameters 110. Other types of optimization functions 170 also may be utilized by the electrochemical models described herein.

In certain embodiments, the electrochemical models cooperate or communicate with the optimization function 170 to estimate desired battery parameters 110. In some examples, an electrochemical model can be applied to simulate battery behavior based on input data and initial parameter estimates, while the optimization function 170 iteratively adjusts these parameters to minimize the difference between the simulated output and measured data, cooperatively refining the battery parameter estimates. This applies to both the reduced-order electrochemical model 140 and the full-order electrochemical model 150.

Prior to estimating the battery parameters 110 for the battery cells 105, one or more preprocessing functions 130 may be executed on the input data 120 (e.g., the input current data 121) derived from each of the battery cells 105 being analyzed. In certain embodiments, the preprocessing function 130 may be configured to perform feature distillation or extraction on the current data 121 (or other input data 120) and the preprocessed current data 121 can be provided as an input to the shallow and/or deep estimation functions described herein. The feature distillation or extraction techniques applied to the current data 121 and/or input data 120 further improve the speed of the battery analysis system 100 in deriving estimates of battery parameters 110, while ensuring the estimates are produced with sufficient accuracy.

In some examples, the initial current data 121 derived from the battery cells 105 may correspond to raw current data having a high frequency and amplitude, which would necessitate extensive simulation time for physics-based models to accurately capture the frequency characteristics. Thus, the preprocessing function 130 can apply one or more feature distillation techniques to reduce the frequency and/or amplitude of the current data 121, thereby significantly reducing the computational requirements typically associated with processing the raw current data. Various techniques can be applied to reduce the frequency and/or amplitude of the input current data 121. In certain embodiments, the preprocessing function 130 may apply Gaussian filtering, Kalman filtering, and/or specially designed convolution kernels to reduce the frequency and/or amplitude of the input current data 121.

In certain embodiments, the preprocessing functions 130 also can be applied to determine or select a reduction metric 131 that quantifies the degree of preprocessing that is performed on the input data 120 and/or which quantifies the degree of which the frequency and amplitude of the current data 121 is reduced. In certain embodiments, the preprocessing functions 130 can execute an evaluation process for selecting an optimized reduction metric 131 that maximizes the reduction in frequency and amplitude of the current data 121 to improve simulation efficiency, while ensuring sufficient accuracy of model simulations.

The manner in which the preprocessing functions 130 identify or select the reduction metric 131 can vary. In certain embodiments, at least one reduced-order electrochemical model 140 and/or at least one full-order electrochemical model 150 (or a combination thereof) can be utilized to evaluate and/or select the reduction metric 131. In some examples, a full-order electrochemical model 150 can be utilized and certain initial parameters of the full-order electrochemical model 150 (e.g., such as the SOC values for the cathode and anode, initial salt concentration, initial solid-phase and electrolyte volume fractions, kinetic reaction rate of the electrodes, etc.) initially can be set to arbitrarily selected values. These values may not be particularly important at this stage and can be re-estimated in subsequent processing stages.

Reference voltage data 132 can then be input into the full-order electrochemical model 150 to generate or determine a benchmark terminal voltage profile 133. In some cases, the reference voltage data 132 may correspond to one or more initial voltage datasets or profiles derived from one or more battery-powered devices. The reference voltage data 132 may include random, dynamic charging/discharging data derived during usage of the one or more battery-powered devices (e.g., during both charging and discharging cycles). In some examples, the reference voltage data 132 may include experimental or testing voltage data that can be utilized as a basis for generating the benchmark terminal voltage profile 133.

The full-order electrochemical model 150 may process the reference voltage data 132 to derive the benchmark terminal voltage profile 133. In certain embodiments, the benchmark terminal voltage profile 133 may comprise a reference voltage curve and/or series of voltage measurements indicating the terminal voltage over a time period, and it may be used as a reference for assessing the quality or sufficiency of other simulated voltage profiles generated by the electrochemical models herein.

After the benchmark terminal voltage profile 133 is determined, the reference voltage data 132 can be preprocessed (e.g., using a Gaussian filter, Kalman filter, convolution kernel, or other distillation means) according to a selected reduction metric 131, and the preprocessed current data 121 can be provided as an input into either the reduced-order electrochemical model 140 or the full-order electrochemical model 150 to generate a simulated terminal voltage profile 134. The simulated terminal voltage profile 134 may comprise a voltage curve and/or series of voltage measurements that are derived via a simulation performed using the preprocessed current data 121.

The simulated terminal voltage profile 134 can be compared with the benchmark terminal voltage profile 133 ascertained in the prior preprocessing operations. The benchmark terminal voltage profile 133 may be utilized assess the quality or sufficiency of the preprocessed current data. For example, if the difference between the simulated terminal voltage profile and the benchmark terminal voltage profile 133 satisfies an error threshold 135 (e.g., it is sufficiently small and/or falls below or within the error threshold 135), the preprocessed input current data can be considered adequately refined, thus indicating that the selected reduction metric 131 used to generate the preprocessed current data is acceptable. Conversely, if the difference between the simulated terminal voltage profile 134 and the benchmark terminal voltage curve does not satisfy the error threshold 135 (e.g., it is too large and/or exceeds the error threshold 135), the preprocessed input current data can be deemed too coarse (e.g., indicating that the selected reduction metric 131 is not acceptable and/or is too high). In the latter scenario, the value of the reduction metric 131 can be reduced to a certain extent (e.g., in some cases, reduced by 50%) and the evaluation process can be re-executed with the modified reduction metric 131. This process can repeat until an acceptable reduction metric 131 is identified. In this manner, the preprocessing functions 130 can identify an optimal or acceptable reduction metric 131 that improves simulation efficiency while maintaining simulation accuracy.

The error threshold 135 used for the comparison of the simulated terminal voltage profile 134 and the benchmark terminal voltage profile 133 can vary and/or can be adjusted or customized based on the desired level of accuracy for the battery parameter estimation process. In some embodiments, the error threshold 135 may be set to a higher value to prioritize computational efficiency, while in other cases, it may be set to a lower value to achieve greater precision in the parameter estimates. In some examples, the error threshold 135 may be set to 15%, such that when the average error or deviation between the simulated terminal voltage profile and the benchmark terminal voltage profile falls below 15%, the estimation process is considered sufficiently accurate. In other implementations, the error threshold 135 may be set to different values, such as 5%, 10%, 20%, or 25%, depending on the desired balance between accuracy and computational speed.

In certain embodiments, the battery analysis system 100 can be configured to generate or determine a diagnostic assessment 180 for each battery cell 105 that is analyzed by the system. The diagnostic assessment 180 for a battery cell 105 can be determined or generated based, at least in part, on one or more of the battery parameters 110 estimated or calculated for the battery cell 105 (e.g., based on one or more degradation parameters 110A, one or more model parameters 110B, one or more thermal parameters 110C, and/or one or more SOH parameters 110D estimated or determined for the battery cell 105).

In some examples, the diagnostic assessment 180 for a battery cell 105 may include a positive diagnostic assessment and/or may indicate that a battery cell 105 is operating under normal conditions in response to determining that one or more battery parameters 110 (e.g., some or all of the battery parameters 110) align with expected values or ranges. In other examples, the diagnostic assessment 180 for a battery cell 105 may include a negative diagnostic assessment and/or may indicate that a battery cell 105 is operating under abnormal conditions in response to detecting that one or more battery parameters 110 deviate from expected values or ranges.

In certain embodiments, one or more mitigation functions 185 may be executed in response to a negative diagnostic assessment for one or more battery cells 105. The mitigation functions 185 may be initiated or executed by the battery analysis system 100 and/or a battery management system that is in communication with the battery analysis system 100. In certain embodiments, these mitigation functions 185 may be implemented to address issues identified by the negative diagnostic assessment and/or to optimize the performance, safety, and longevity of the affected battery cells 105 (or device containing the battery cells 105). The types of mitigation functions 185 executed can vary and, in some cases, may depend upon the particular battery parameters identified as deviating from expected operating conditions.

In certain embodiments, executing a mitigation function 185 can adjust or modify operational parameters, performance, and/or settings corresponding to one or more affected battery cells 105. This could involve modifying the voltage, current, temperature, and/or, resistance corresponding to the one or more battery cells 105. Additionally, or alternatively, this can include modifying one or more parameters or settings to adjust the charge rate, discharge rate, state of charge, depth of discharge, charging time, discharging time, power output, cycle count, internal pressure, cooling rate, thermal management settings, balancing parameters, maximum charge voltage, minimum discharge voltage, maximum charge current, maximum discharge current, charging protocol, discharging protocol, idle time, load distribution, power allocation, cell grouping, bypass settings, fault tolerance levels, and/or sensitivity levels corresponding to the one or more battery cells 105. Other parameters and/or settings also may be modified or adjusted. In some scenarios, modifying or adjusting the parameters, performance, and/or settings corresponding to one or more affected battery cells 105 can correct and/or mitigate a condition that caused or generated the negative diagnostic assessment.

In certain embodiments, executing a mitigation function 185 can implement isolation procedures for one or more battery cells 105 in response to detecting a negative diagnostic assessment corresponding to those cells. In some examples, the isolation procedures may involve electrically disconnecting or bypassing the affected battery cells 105 (e.g., from a battery pack or system that includes the battery cells 105) to prevent potential safety hazards (e.g., overheating or fire hazards) or further degradation. In certain embodiments, isolation of a battery cell 105 may be achieved through the activation of switches, relays, or other circuit interruption mechanisms integrated within a battery management system or device corresponding to the battery cell 105.

In certain embodiments, the mitigation functions 185 may trigger the transmission or sending of alerts when negative diagnostic assessments are detected for one or more battery cells 105. These alerts could be sent to a vehicle or device containing the affected battery cells (and/or to maintenance personnel, technical service providers, or device operators), and can identify details related to the negative assessment and/or indicate that the one or more battery cells 105 should be replaced.

The battery analysis system may execute or implement other types of mitigation functions 185 in addition to those mentioned in this disclosure.

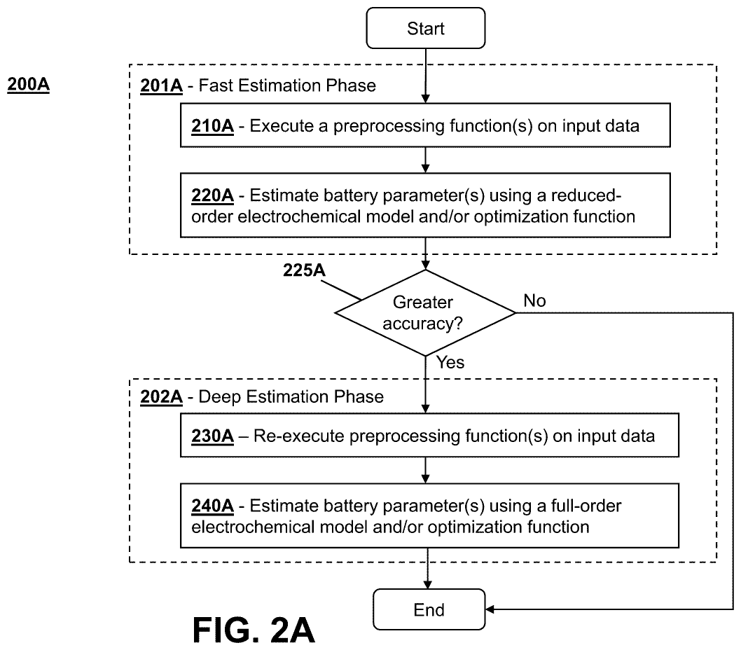

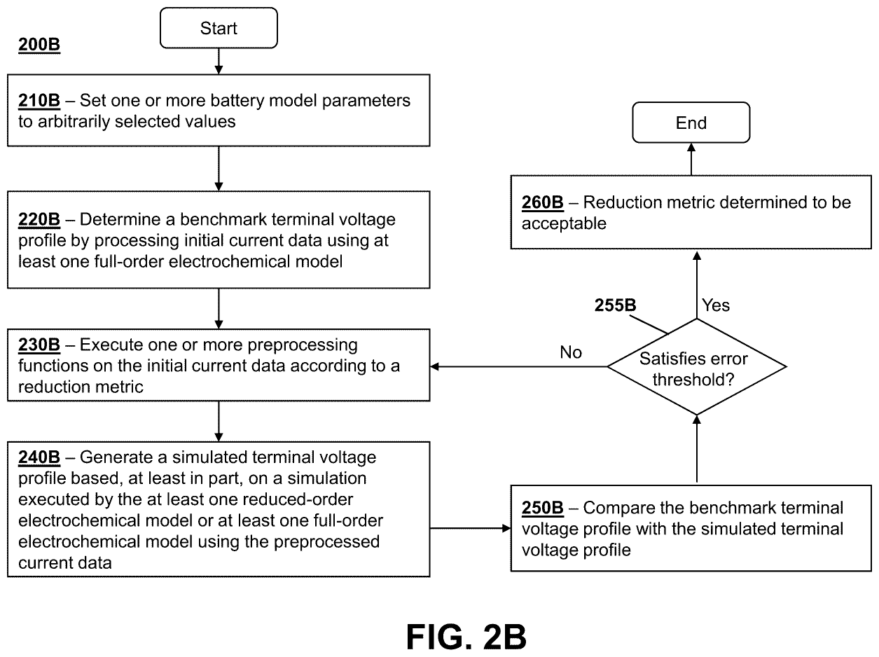

FIG. 2A is a flow chart of an exemplary method 200A for performing battery parameter estimation according to certain embodiments. Method 200A is merely exemplary and is not limited to the embodiments presented herein. Method 200A can be employed in many different embodiments or examples not specifically depicted or described herein. In some embodiments, the steps of method 200A can be performed in the order presented. In other embodiments, the steps of method 200A can be performed in any suitable order. In still other embodiments, one or more of the steps of method 200A can be combined or skipped. In many embodiments, the battery analysis system 100 can be configured to perform method 200A and/or one or more of the steps of method 200A. In these or other embodiments, one or more of the steps of method 200A can be implemented as one or more computer instructions configured to run at one or more processing devices 102 and configured to be stored at one or more non-transitory storage devices 101. Such non-transitory memory storage devices 101 can be part of a computer system such as system 100A and/or battery analysis system 100.

In this exemplary method 200A, steps 210A and 220A may be performed as part of fast estimation phase 201A (which also may be referred to as a shallow or reduced-order estimation phase) and steps 230A and 240A may be performed as part of deep estimation phase 202A (which also may be referred to as a full-order estimation phase).

In step 210A, one or more preprocessing functions 130 are executed on input data 120. The input data 120 may comprise, inter alia, current data 121 (e.g., raw current data having a relatively high frequency and amplitude) acquired from one or more battery cells 105. The one or more preprocessing functions 130 may be executed to reduce the frequency and amplitude corresponding to the current data 121 based on a selected reduction metric 131. In some embodiments, the extent of the preprocessing performed on the current data 121 can be determined by the reduction metric 131.

In step 220A, one or more battery parameters 110 are estimated using a reduced-order electrochemical model 140 and/or an optimization function 170. The reduced-order electrochemical model 140 and the optimization function 170 may cooperate to jointly estimate the one or more battery parameters 110. In some examples, the one or more battery parameters 110 estimated in this step may comprise one or more battery degradation parameters 110A, one or more battery model parameters 110B, one or more thermal parameters 110C, one or more SOH parameters 110D, and/or other types of battery parameters 110.

In step 225A, a determination is made as to whether the one or more estimated battery parameters 110 should be refined and/or estimated with greater accuracy. In response to determining that further refinement and/or accuracy is not needed or desired, the method 200A proceeds to the end block and terminates. In this scenario, the battery parameter estimations performed in step 220A may be utilized to represent the final battery parameters 110 for the one or more battery cells 105. Otherwise, if it is determined that further refinement and/or accuracy is not needed or desired, the method 200A proceeds to step 230A.

In step 230A, one or more preprocessing functions 130 may be re-executed on the input data 120. For example, the one or more preprocessing functions 130 may be executed on input data 120 using a second reduction metric 131 that is different from the reduction metric 131 utilized in step 210A (e.g., a second reduction metric 131 that reduces the frequency and amplitude of current data 121 to a lesser extent relative to the first reduction metric 131).

In some embodiments, step 230A may be optional and/or may be omitted. For example, rather than re-executing the one or more preprocessing functions 130, the input data 120 (e.g., raw current data 121) may be used in step 240A to estimate the one or more battery parameters 110 and, therefore, no preprocessing may be performed.

In step 240A, one or more battery parameters 110 are estimated using a full-order electrochemical model 150 and/or an optimization function 170. The full-order electrochemical model 150 and the optimization function 170 may cooperate to jointly estimate the one or more battery parameters 110. Again, the one or more battery parameters 110 may comprise one or more battery degradation parameters 110A, one or more battery model parameters 110B, one or more thermal parameters 110C, one or more SOH parameters 110D, and/or other types of battery parameters. The battery parameter estimations performed in step 240A may be utilized to represent the final battery parameters 110 for the one or more battery cells 105. After the final battery parameters 110 for the one or more battery cells 105 are determined, the method 200A proceeds to the end block and terminates.

In certain embodiments, the method 200A in FIG. 2A also may include a step of determining a diagnostic assessment 180 on one or more battery cells 105 corresponding to the input data. This diagnostic assessment step may be executed after step 220A, step 240A, and/or after both steps.

In certain embodiments, the method 200A in FIG. 2A also may include a step of executing a mitigation function 185 in response to detecting a negative or abnormal diagnostic assessment for one or more battery cells 105.

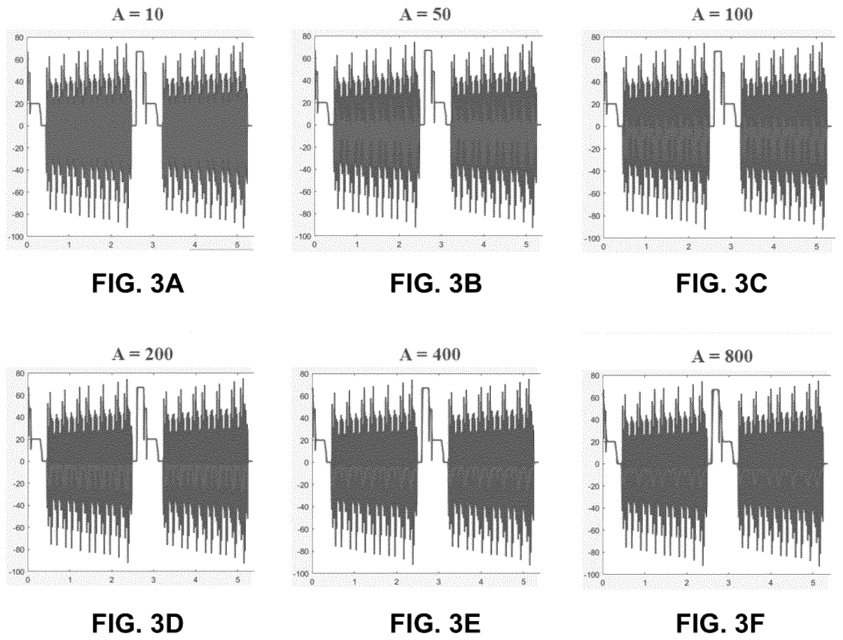

FIGS. 3A-3F include graphs showing comparisons of current data 121 before and after a preprocessing function 130 is applied. In these graphs, the y-axis indicates current values and the x-axis indicates time (the unit of the x-axis is 1×10⁴ seconds). The blue curves in the graphs correspond to raw current data 121 prior to preprocessing, and the red curves correspond to the preprocessed current data 121. Different reduction metrics 131 are used in each of the graphs (which are indicated by “A” above each of the graphs). In this example, larger A values (or reduction metrics 131) result in a more significant reduction of frequency and amplitude than lower A values.

FIG. 3A is a graph illustrating a comparison of raw current data before and after preprocessing when a first reduction metric is set to ten (10). FIG. 3B is a graph illustrating a comparison of raw current data before and after preprocessing when a second reduction metric is set to fifty (50). FIG. 3C is a graph illustrating a comparison of raw current data before and after preprocessing when a third reduction metric is set to one hundred (100). FIG. 3D is a graph illustrating a comparison of raw current data before and after preprocessing when a fourth reduction metric is set to two hundred (200A). FIG. 3E is a graph illustrating a comparison of raw current data before and after preprocessing when a fifth reduction metric is set to four hundred (400). FIG. 3F is a graph illustrating a comparison of raw current data before and after preprocessing when a sixth reduction metric is set to eight hundred (800).

As explained above, prior to estimating the battery parameters 110 for one or more battery cells 105 under analysis, one or more preprocessing functions 130 can be executed to perform feature distillation on the input current data 121. The high-frequency nature of raw current data (as shown by the blue curves in FIGS. 3A-3F) would typically involve extensive simulation time for physics-based models to accurately capture the frequency characteristics. Thus, the preprocessing of the current data 121 can be advantageous because it extracts data that permits the optimization function 170 used by the shallow estimation function 145 and/or deep estimation function 155 to accurately calculate the parameter estimation results, while simultaneously reducing the computational load.

Various techniques can be applied to select an optimal or appropriate reduction metric 131 for reducing computational loads of the reduced-order electrochemical model(s) 140 and/or full-order electrochemical model(s) 150, while ensuring that the estimates produced by the models are sufficiently accurate.

FIG. 2B is a flow chart of an exemplary method 200B that can be applied to identify or select a reduction metric 131 according to certain embodiments. Method 200B is merely exemplary and is not limited to the embodiments presented herein. Method 200B can be employed in many different embodiments or examples not specifically depicted or described herein. In some embodiments, the steps of method 200B can be performed in the order presented. In other embodiments, the steps of method 200B can be performed in any suitable order. In still other embodiments, one or more of the steps of method 200B can be combined or skipped. In many embodiments, the battery analysis system 100 and/or preprocessing functions 130 can be configured to perform method 200B and/or one or more of the steps of method 200B. In these or other embodiments, one or more of the steps of method 200B can be implemented as one or more computer instructions configured to run at one or more processing devices 102 and configured to be stored at one or more non-transitory storage devices 101. Such non-transitory memory storage devices 101 can be part of a computer system such as system 100A and/or battery analysis system 100.

In step 210B, one or more of the battery model parameters are set to arbitrarily selected values. These arbitrarily set battery model parameters may include parameters utilized by a reduced-order electrochemical model 140 and/or a full-order electrochemical model 150 to run simulations on one or more battery cells 105. In some examples, some or all of the following battery model parameters can be set to arbitrary values: parameter(s) indicating an initial state of charge (SOC) values for the cathode and anode; parameter(s) indicating an initial salt concentration; parameter(s) indicating an initial solid-phase and electrolyte volume fractions; and/or parameter(s) indicating kinetic reaction rate of the electrodes. Other parameters of the electrochemical models(s) also may be arbitrarily selected values. The parameters that are arbitrarily set in this step can be re-estimated in subsequent parameter estimation procedures, and may not be particularly useful for identifying an appropriate reduction metric 131.

In step 220B, a benchmark terminal voltage profile 133 is determined by processing initial current data using at least one full-order electrochemical model 150. The initial current data 121 may correspond to reference voltage data 132, such as raw or experimental current data, having a relatively high frequency and amplitude.

In step 230B, one or more preprocessing functions 130 are executed on the initial current data (e.g., using a Gaussian filter or other frequency/amplitude reducing means) according to a reduction metric 131. As explained above, the reduction metric 131 can quantify the degree to which preprocessing is performed and/or the extent to which the frequency and amplitude of the raw current data is reduced. The one or more preprocessing functions 130 output preprocessed current data having a reduced frequency and amplitude.

In step 240B, a simulated terminal voltage profile 134 is generated based, at least in part, on a simulation executed by the at least one reduced-order electrochemical model 140 or at least one full-order electrochemical model 150 using the preprocessed current data. The simulated terminal voltage profile 134 may be generated based on the preprocessed current data and the accuracy of the simulated terminal voltage profile 134 may be correlated to the reduction metric 131 that was utilized to generate the preprocessed current data. As explained throughout this disclosure, an optimization function 170 may operate in parallel with the at least one reduced-order electrochemical model 140 or at least one full-order electrochemical model 150 to generate the simulated terminal voltage profile 134.

In step 250B, the benchmark terminal voltage profile 133 is compared with the simulated terminal voltage profile 134.

In step 255B, a determination is made as to whether the difference between the simulated terminal voltage profile 134 and the benchmark terminal voltage profile 133 satisfies an error threshold 135. The error threshold 135 may indicate a numerical value or range that can be used to determine whether the simulated terminal voltage profile 134 is sufficiently accurate for estimation purposes. In certain embodiments, the average error (e.g., an absolute average error or AAE) or deviation between the simulated terminal voltage profile 134 and the benchmark terminal voltage profile 133 may be computed, and compared to the error threshold 135. In some examples, the error threshold 135 may be set to 15% such that, when the average error or deviation is below 15%, the simulated terminal voltage profile 134 is determined to be sufficiently close to benchmark terminal voltage profile 133 (and, conversely, is determined to be too large when the average error or deviation is above 15%). The error threshold 135 can be set other values (e.g., 1%, 5%, 10%, 20%, 25%, etc.) based on the desired balance between accuracy and computational times.

If the difference between the simulated terminal voltage profile 134 and the benchmark terminal voltage profile 133 is sufficiently small (e.g., below the error threshold 135), the method 200B proceeds to step 260B. In step 260B, the reduction metric 131 is determined to be acceptable and/or is selected, and the method terminates at the end block.

On the other hand, if the difference between the simulated terminal voltage profile 134 and the benchmark terminal voltage profile 133 is too large (e.g., exceeds the error threshold 135), this may indicate the preprocessed current data is too coarse and/or is not acceptable. In this scenario, the method 200B proceeds back to step 230B and a new reduction metric 131 can be selected to generate the preprocessed current data. Steps 230B, 240B, 250B and 255B can be continuously repeated until an acceptable reduction metric 131 is identified that is able to generate the preprocessed current data with sufficient accuracy or quality. For example, in each iteration, the reduction metric 131 utilized to generate the preprocessed current data may be decreased (e.g., reduced by half or some other pre-determined percentage), thereby increasing the frequency and amplitude of the preprocessed current data generated in a current iteration. The quality or sufficiency of the preprocessed current data in each iteration can be re-evaluated by comparing the difference between the simulated terminal voltage profile 134 and the benchmark terminal voltage profile 133 until an iteration is reached in which the preprocessed current data utilized to generate a corresponding simulated terminal voltage profile 134 is determined to be sufficient and/or satisfies the error threshold 135.

Returning to FIG. 1B, the reduction metric 131 selected by the preprocessing function 130 can operate to quickly narrow down the range of values utilized by the optimization function 170 and/or electrochemical models to estimate the battery parameters 110. In some embodiments, the reduction metric 131 utilized to derive preprocessed current data 121 for a reduced-order electrochemical model 140 can be greater than a reduction metric 131 utilized to derive preprocessed current data 121 for a full-order electrochemical model 150. In some examples, the reduction metric 131 utilized to derive preprocessed current data 121 for a reduced-order electrochemical model 140 can be within a range of one hundred (100) to five hundred (500) (e.g., may be set to 100, 150, 200, 300, 400, or 500), while the reduction metric 131 utilized to derive preprocessed current data 121 for a full-order electrochemical model 150 can be below one hundred (100) (e.g., may be set to 10, 25, 50, 75, or 99).

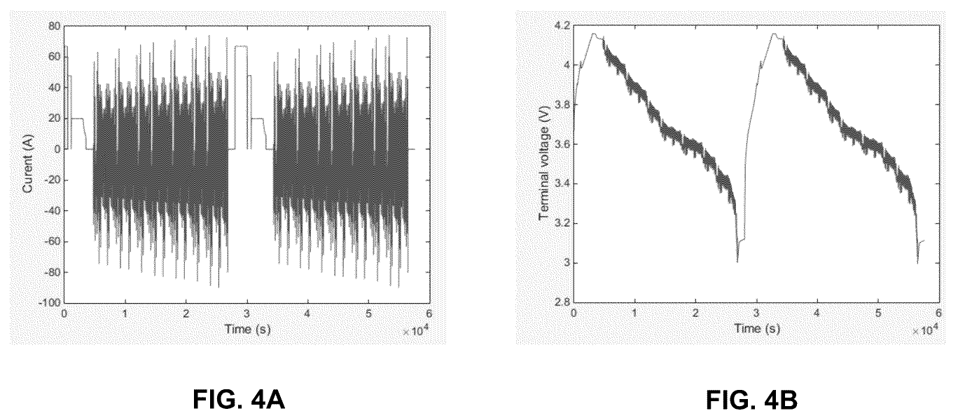

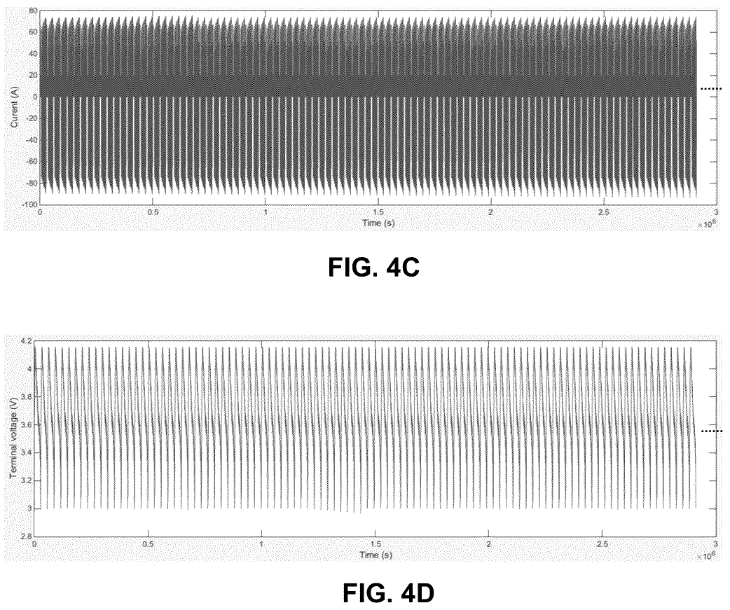

The description below, with reference to FIGS. 4A-4D, 5A-50, 6A-6D, 7A-7J, 8A-8F, and 9A-9D, illustrates an exemplary procedure for estimating battery parameters 110 according to certain embodiments, as well as testing results associated with executing the procedure. The procedure can initially involve estimating an initial set of model parameters 110B for one or more battery cells 105, which can be used to modify certain variables or settings of the electrochemical models (e.g., a reduced-order electrochemical model 140 and/or a full-order electrochemical model 150) to account for specific physical changes that occur during battery operation, such as alterations in the active surface area caused by electrode volume changes, particle contraction gaps, and/or other changes in the one or more battery cells 105. After estimating these initial model parameters 110B, the procedure then proceeds to estimate one or more degradation parameters 110A and/or one or more thermal parameters 110C for the one or more battery cells 105. In some cases, the procedure also may be extended or adapted to estimate one or more SOH parameters 110D.

The exemplary procedure described below utilizes two types of lithium-ion battery cells for demonstration purposes (which can be referred to as “battery 001” and “battery 002,” respectively).

In a first stage of the procedure, certain model parameters 110B corresponding to the battery cells 105 are estimated. In some examples, the model parameters 110B estimated in this stage can include the initial state of charge (SOC) of the cathode and anode, the initial salt concentration in the electrolyte, the tortuosity of the anode and cathode, the kinetic reaction rate of the particle surface, and/or other adjustment factors. As mentioned above, these model parameters 110B can modify variables in the electrochemical model affected by specific mechanisms, such as changes in active surface area due to electrode volume changes and particle compaction gaps.

FIG. 4A illustrates the input current data of battery 001 in a dynamic driving condition without preprocessing, while FIG. 4B illustrates the corresponding measured cell terminal voltage curve (showing two cycles as an example) of the battery cell 001. In FIGS. 4A and 4B, the x-axis represents time (the unit of the x-axis is 1×10⁴ seconds). The y-axis in FIG. 4A indicates current (A), and the y-axis in FIG. 4B indicates terminal voltage (V). The terminal voltage curve illustrated in FIG. 4B may represent a benchmark terminal voltage profile 133 that can be used as a basis for comparison at later stages of the procedure.

The input current data for the Li-ion battery cells (battery 001 and battery 002) covers both the charging and discharging stages, showing various random amplitudes during these processes. To estimate the model parameters 110B, certain parameters (e.g., degradation and thermal parameters) of the model can be held constant. An initial selection space or range for each battery parameter can be defined, from which the optimization function 170 will select values. The experimental current and voltage data for the first 100,000 seconds can be used for processing the estimation. During this phase, the other parameters may remain constant.

After data preprocessing is performed (e.g., in some cases, using a reduction metric 131 value of 200), the input current data can be accessed and utilized by the shallow estimation function 145. As explained above, the shallow estimation function 145 can utilize a reduced-order electrochemical model 140 (e.g., a revised or modified single-particle model) and an optimization function 170 to estimate the model parameters 110B. The reduced-order electrochemical model 140 may offer fast calculation speed and high accuracy within a specific range of charging and discharging C-rates (e.g., 2.5 C or above). Using the preprocessed input current data and battery parameters (including the model parameters 110B and/or other parameters), the reduced-order electrochemical model 140 simulates and outputs a terminal voltage data curve (e.g., a simulated terminal voltage profile 134), which is compared with the benchmark terminal voltage profile 133 in FIG. 4B to calculate an absolute average error (AAE). If the AAE exceeds a threshold error value ξ (e.g., 30 mV), the shallow estimation function 145 can be re-executed to continue optimizing the model parameters 110B until the AAE falls below ξ. The optimized model parameters 110B resulting in the lowest AAE can be stored or recorded as the battery parameter estimation results of the shallow estimation function 145.

In some embodiments, the deep estimation function 155 can be applied to further refine the model parameters 110B. In this scenario, the battery parameter estimation results generated by the shallow or reduced-order estimation function 145 also can serve to narrow the selection space for each parameter that the optimization function 170 computes in the deep estimation stage. Reducing the selection space can be a significant driving factor in reducing computational times, as sweeping within a large selection space can significantly increase the iteration count needed for convergence, thereby consuming more time. For example, estimating the initial cathode SOC with a broad initial selection space (0.05 to 0.95) might require 100,000 iterations for the optimization algorithm to converge, assuming other battery parameters are constant. However, after several iterations of the fast estimation process, it may be observed that when the cathode SOC value falls within the range of 0.5 to 0.75, the simulated terminal voltage curve is more likely to achieve an AAE below the error threshold value (e.g., 50 mV) when compared to the benchmark terminal voltage curve. Thus, the selection space for the cathode SOC can be narrowed from 0.05-0.95 to 0.5-0.75, decreasing the iteration count to around 2,000 and significantly reducing optimization time. This reduction can be particularly beneficial for the deep estimation function 155, as the simulation time for full-order electrochemical models 150 is longer than for reduced-order electrochemical models 140. Moreover, the shallow estimation process can be repeated multiple times to further narrow down the selection space of each model parameter 110B and to avoid local optimization traps. This iterative approach can refine the parameter ranges for subsequent rounds of the fast estimation process, thereby accelerating the convergence of the optimization process.

In some embodiments, the deep estimation function 155 can be executed if it is determined that higher accuracy is desired (e.g., a lower AAE threshold value ξ, such as below 15 mV) following the fast estimation stage. In some examples, further refinement by the deep estimation function 155 may be desired in scenarios where the charging or discharging rate is relatively low, such as having a C-rate below 2.5.

In some embodiments, the input current data 121 can be preprocessed again with a smaller reduction metric 131 (e.g., below 50). Alternatively, the input current data 121 can forego any preprocessing. In either scenario, the current data can be accessed by, or input to, the deep estimation function 155, which utilizes the full-order electrochemical model 150 and the optimization function 170 for higher accuracy estimations. As mentioned above, the selection space for each parameter in the deep estimation process can be based on, or derived from, the results of the fast or reduced-order estimation stage. The model parameters 110B can be optimized to minimize the AAE between the simulated terminal voltage profile 134 generated by the full-order electrochemical model 150 and the benchmark terminal voltage profile 133. The most optimized parameters, leading to the minimal AAE, can be recorded as the final model parameters 110B in the deep estimation process.

As demonstrated above, the model parameters 110B corresponding to the battery cells 105 (e.g., battery 001 and 002) can be ascertained using either the shallow estimation function 145 and/or a combination of the shallow estimation function 145 and deep estimation function 155, depending upon the level of accuracy desired.

After estimating the initial parameters of the battery cells 105, the degradation parameters 110A and/or thermal parameters 110C of the battery cells 105 can be estimated. Since battery aging and degradation accumulate over longer time periods, estimating degradation parameters 110A (e.g., such as cathode and anode SEI formation and evolution rates, lithium-plating rates, transition metal dissolution and deposition rates, and/or electrolyte decomposition rates) may involve usage of a significantly larger dataset.

In some examples, as shown in FIGS. 4C and 4D, experimentally measured current and terminal voltage data under dynamic driving conditions lasting 1×10⁷ to 3×10⁷ seconds may be used for estimating the degradation parameters 110A. During this process, the initial battery parameters (e.g., initial cathode and anode SOC, initial salt concentration, kinetic reaction rate of the cathode and anode surfaces) and battery model parameters (e.g., particle radius, electrode and separator thickness, electrode porosity) may be held constant. In FIGS. 4C and 4D, the x-axis represents time (the unit of the x-axis is 1×10⁶ seconds). The y-axis in FIG. 4C indicates current (A) of battery 002, and the y-axis in FIG. 4D indicates terminal voltage (V) of battery 002.

Initially, the fast or shallow estimation function 145 can be executed to quickly estimate the battery degradation parameters 110A and narrow down the selection space for each parameter that the optimization function 170 will consider during a later deep estimation process. The preprocessed current data, with a relatively large reduction metric 131 (e.g., with a value of 200), can be utilized by the reduced-order electrochemical model 140. The degradation parameters 110A can be optimized until the simulated terminal voltage profile 134 has an average absolute error (AAE) below a specific error threshold value & (e.g., below 50 mV) in the same or similar manner described above. Again, if higher accuracy is desired, the deep estimation function 155 can be applied. In this scenario, the input current data (with minimal or no preprocessing) can be accessed by, or input to, the full-order electrochemical model 150 and the optimization function 170. Final estimation results for the degradation parameters 110A may be obtained from the optimization function 170 when the AAE of the simulated terminal voltage curve is minimized (e.g., below 25 mV).

Thus, similar to the model parameter estimation process, the degradation parameters 110A for the battery cells 105 (e.g., battery 001 and 002) can be estimated using either the shallow estimation function 145 and/or a combination of the shallow estimation function 145 and deep estimation function 155, depending upon the level of accuracy desired.

The same or similar techniques also can be extended to estimate SOH parameters 110D for the battery cells 105 including, but not limited to, SOH parameters 110D that represent aging of the battery cells 105. In certain embodiments, because estimating actual or real degradation parameters can be extremely time-consuming, the battery analysis system 100 may estimate the SOH parameters 110D utilizing certain model parameters 110B that can be used to derive aging assessments. In some examples, the SOH parameters 110D of a battery cell 105 may be derived, at least in part, using model parameters 110B indicating the tortuosity and porosity of the electrodes, the active surface area of the particles, and/or the equivalent kinetic rate of the particle surface. These model parameters 110B can allow the aging of the battery cell 105 to be determined more quickly and efficiently compared to techniques that rely on actual degradation parameters. The rapid aging assessment techniques described herein permit the battery analysis system 100 to estimate SOH parameters 110D for on-board and/or real-time applications.

In certain embodiments, the battery analysis system 100 can derive the SOH parameters 110D corresponding to a battery cell at various operational stages, such as an initial stage when a battery cell (or multiple battery cells) is manufactured or installed in a battery operated device (e.g., when the SOH is expected to be at or near 100%), an early life stage (e.g., when the SOH is slightly declined after minimal usage), a middle life stage (e.g., when the SOH is expected to gradually decline), and end-of-life stage (e.g., when the battery cell is SOH is expected to be too low for practical usage). In scenarios where the battery cell(s) 105 are installed in a vehicle, the operational stages may additionally, or alternatively, correspond to different stages of the vehicle's usage.

In certain embodiments, to evaluate the SOH parameters 110D of a given battery cell 105, the battery model parameters 1110B may be periodically updated or estimated at various checking points for each operational stage. The same or similar process described above to estimate the initial model parameters 110B can be used at each checking point. For example, the experimental or raw input data 120 spanning 100,000 seconds from each checking point can be selected or extracted, and the input current data 121 can be first preprocessed with a larger reduction metric 131 (e.g., a value of 200). Thereafter, the shallow estimation function 145, which leverages at least one reduced-order electrochemical model 140 and the optimization function 170, can be executed to quickly estimate the equivalent battery model parameters 110B at a given point in time. Again, this process helps narrow down the selection space for the deep estimation function 155 and, if greater accuracy is desired, the deep estimation function 155 can be executed to further refine the battery model parameters 110B at each checking point. In this step, the results from the shallow estimation function 145 can be calibrated. In executing the deep estimation function 155, the current data 121 (with minimal or no preprocessing) can be input to the full-order electrochemical model 150 and optimization function 170. At each checking point, the most optimized battery model parameters 110B correspond to those that result in the simulated terminal voltage profile 134 (calculated from the corresponding checking point) having the minimum AAE when compared to the benchmark terminal voltage profile 133. These optimized model parameters 110B may then be utilized to derive the estimate updated SOH parameters 110D at each checking point, which can represent and/or assess the aging of the battery cell 105 at the given point in time.

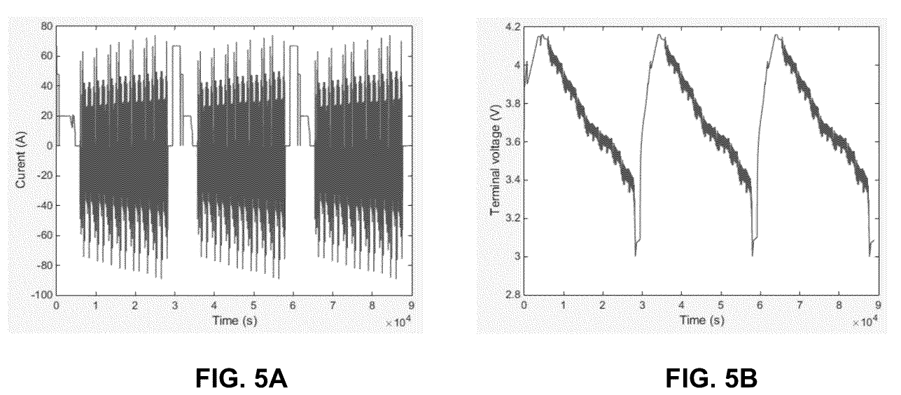

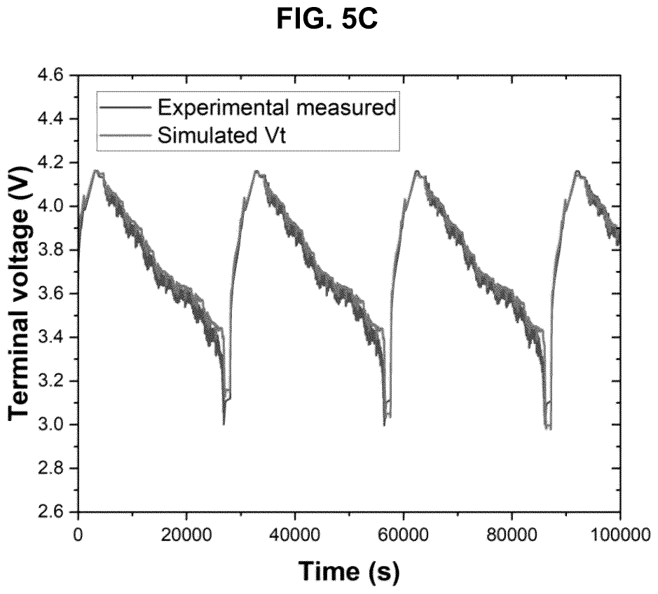

FIGS. 5A-C and 6A-6D illustrate exemplary testing results that were produced according to certain embodiments of the battery analysis system 100.

FIG. 5A illustrates raw current data that was measured from of battery 001 and input to the battery analysis system 100 during testing, and FIG. 5B illustrates the corresponding cell terminal voltage curve or profile for the first three cycles of battery 001 (spanning the first 90,000 seconds).

In accordance with certain embodiments disclosed herein, a shallow estimation function 145 was used to identify the initial model parameters 110B for the battery cell 105. In this example, the shallow estimation function 145 included a reduced-order electrochemical model 140 (e.g., a modified single-particle-model) and an optimization function 170 (e.g., which included a machine learning-based pruner/sampler algorithm) to identify the model parameters 110B. These estimated model parameters 110B parameters included the initial state of charge (SOC) of the anode and cathode (SOC_{0,neg} and SOC_{0,pos}), initial salt concentration (cₑ₀), tortuosity of the cathode and anode (τ_{neg} and τₚₒₛ), kinetic reaction rates of the anode and cathode (k_{neg} and kₚₒₛ), and the solid diffusion coefficients of the anode and cathode particles (D_{s,neg} and D_{s,pos}). The identification of these parameters is based on three cycles of random field data, spanning the first 90,000 seconds of raw current data. The initial selection space for each battery model parameter 110B can be chosen from the ranges shown in Table 1, which is reproduced below.

TABLE 1

| Battery initial parameters | Lower limit | | Upper limit | |
|---|---|---|---|---|
| SOC_{0, neg} | 0.1 | | 0.5 | |
| SOC_{0, pos} | 0.5 | | 0.9 | |
| cₑ₀ | 500 | mol/m³ | 1500 | mol/m³ |
| T_{neg} | 0.5 | | 5 | |
| Tₚₒₛ | 0.5 | | 5 | |
| k_{neg} | 1 × 10⁻¹³ | m/s | 1 × 10⁻¹⁰ | m/s |
| kₚₒₛ | 1 × 10⁻¹³ | m/s | 1 × 10⁻¹⁰ | m/s |
| D_{s, neg} | 1 × 10⁻¹⁵ | m²/s | 1 × 10⁻¹² | m²/s |
| D_{s, pos} | 1 × 10⁻¹⁵ | m²/s | 1 × 10⁻¹² | m²/s |

During testing, a total of ten groups of battery initial parameter estimation optimizations were processed in parallel through the shallow estimation” function 145, with each group undergoing 1000 epochs of optimization by the optimization function 170. After completing the estimations for all ten groups, the most optimized battery initial parameters from each group were identified. These parameters were selected based on the minimum AAE between the simulated terminal voltage profiles 134 and benchmark terminal voltage profiles 133 within each group. The ten sets of optimized battery model parameters 110B were then re-imported into the reduced-order electrochemical model 140, and the simulated terminal voltage profiles 134 were compared with the benchmark terminal voltage profiles 133.

FIG. 5C illustrates an example of one of the comparisons that were performed. In particular, FIG. 5C shows the comparison of the benchmark terminal voltage profile 133 (black curve) and the simulated terminal voltage profile 134 (red curve) based on the most optimized battery model parameters 110B (in this case, the AAE of the simulated terminal voltage is 29.8 mV). It can be seen that the simulated voltage curve (Vt) overall matches very well with the benchmark voltage curve. The most optimized initial model parameters 110B after the shallow estimation function 145 was executed is summarized in Table 2, which is reproduced below.

TABLE 2

| Battery initial parameters | Most optimized value | |
|---|---|---|
| SOC_{0, neg} | 0.4678 | |
| SOC_{0, pos} | 0.5271 | |
| cₑ₀ | 1022.2149 | mol/m³ |
| T_{neg} | 1.37 | |
| Tₚₒₛ | 1.43 | |
| k_{neg} | 1.1646 × 10⁻¹¹ | m/s |
| kₚₒₛ | 6.7234 × 10⁻¹¹ | m/s |
| D_{s, neg} | 3.6466 × 10⁻¹⁴ | m²/s |
| D_{s, pos} | 3.1511 × 10⁻¹⁴ | m²/s |

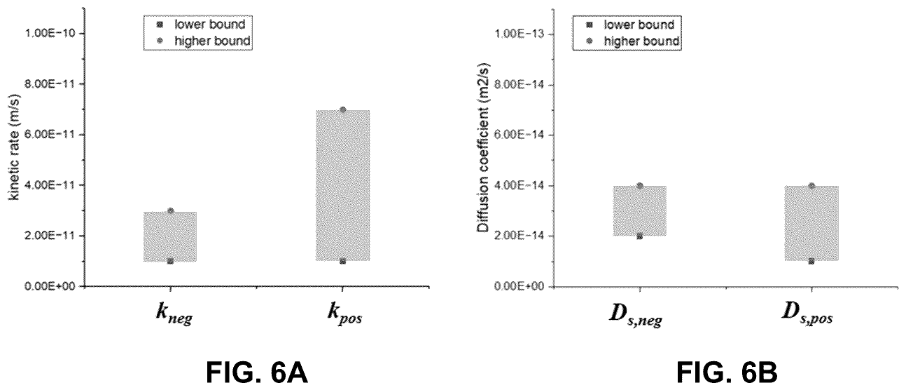

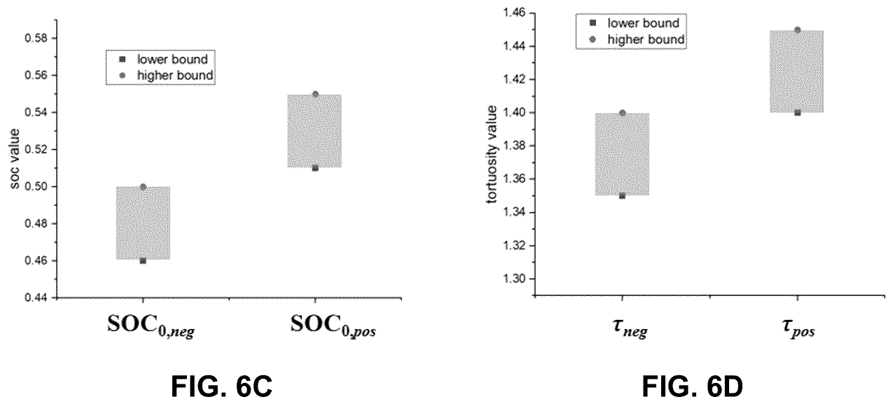

Additionally, the value range of the selection space for each initial battery model parameter 110B can be narrowed (as shown in FIGS. 6A-6D), which can be further used for accelerating the deep estimation function. FIG. 6A shows the narrowed parameter range for a kinetic rate parameter. FIG. 6B shows the narrowed parameter range for a diffusion coefficient parameter. FIG. 6C shows the narrowed parameter range for a SOC value parameter. FIG. 6D shows the narrowed parameter range for a tortuosity parameter.

To represent battery aging conditions for SOH parameters 110D, the equivalent battery model parameters 110B can be re-estimated for different checkpoints. The initial battery model parameters, including SOC_{0,neg}, SOC_{0,pos}, cₑ₀, D_{s,neg}, and D_{s,pos} (shown in FIGS. 6A-6D), can be fixed, while the other model parameters 110B are re-estimated at each checkpoint. The model parameters 110B updated at each checkpoint can include the solid-phase volume fraction of the anode and cathode (ε_{neg} and εₚₒₛ), the tortuosity of the anode and cathode (τ_{neg} and τₚₒₛ), the kinetic reaction rate of the anode and cathode particle surfaces, and the adjustment factors for the active surface area of the anode and cathode.

After the shallow estimation function 145 is applied, the updated equivalent battery model parameters, along with the unchanged parameters, can be imported into the reduced-order electrochemical model 140. The simulated terminal voltage profile 134 can then be compared with the experimentally measured or benchmark terminal voltage profile 133 within each checking window.

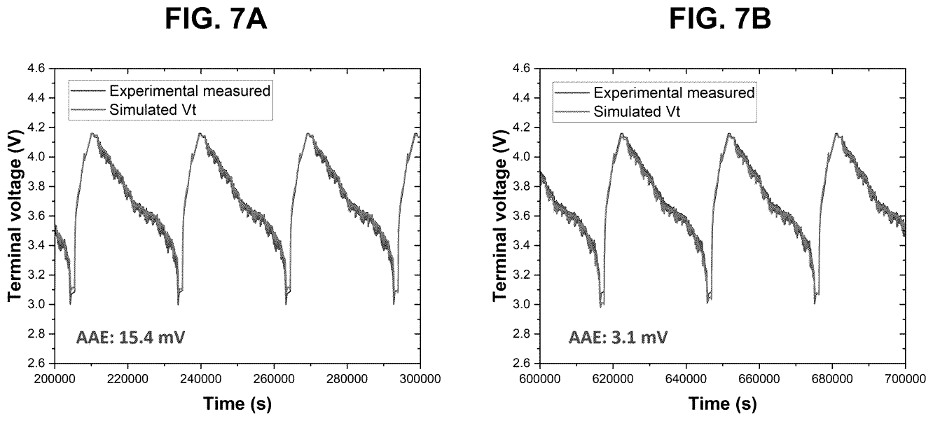

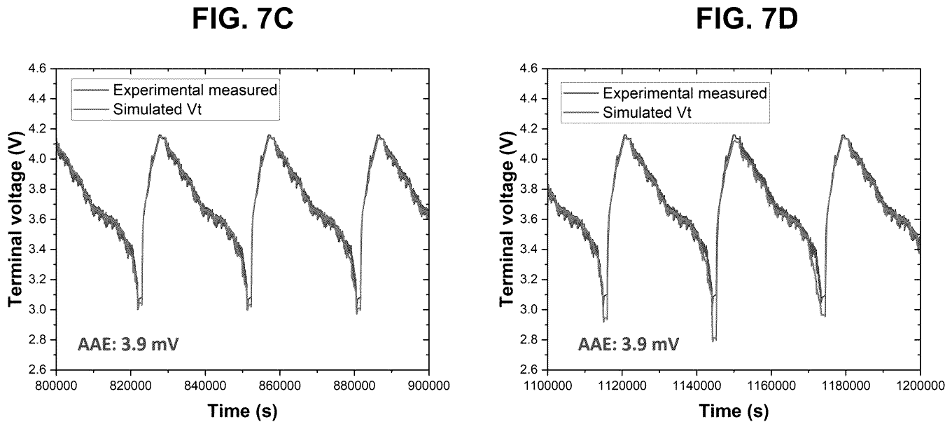

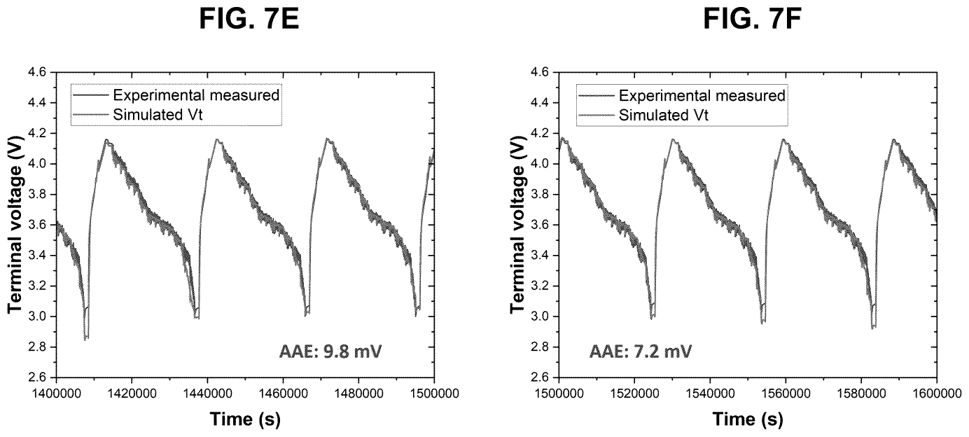

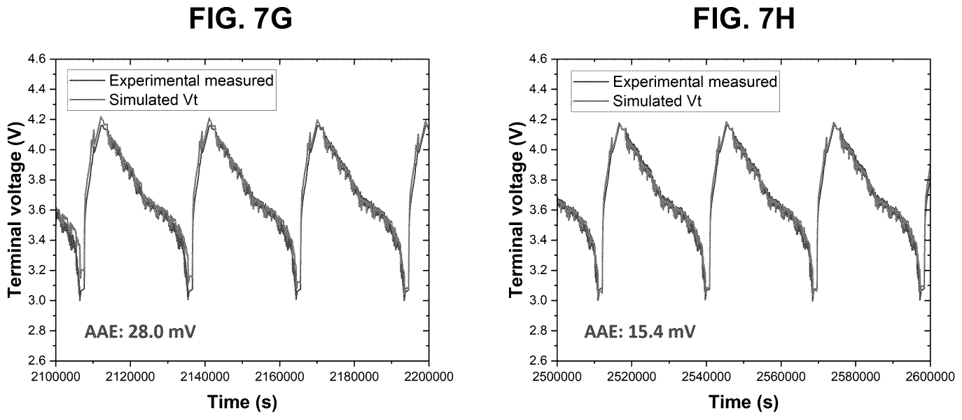

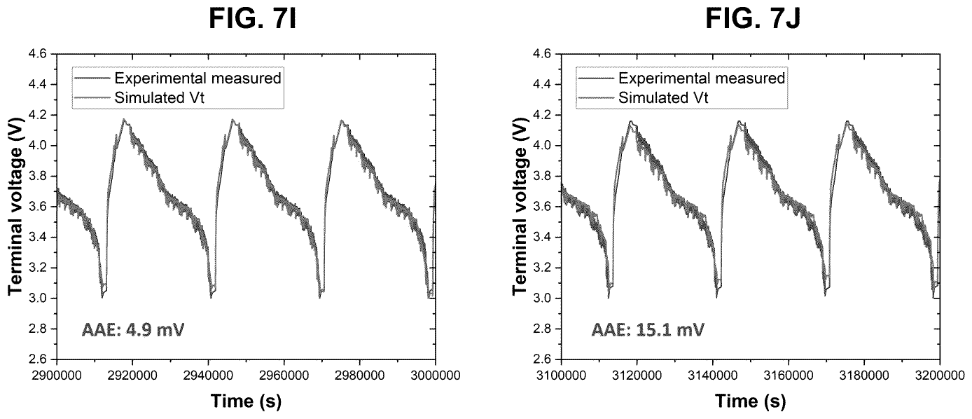

FIGS. 7A-7J illustrate comparisons of the corresponding terminal voltage profiles. It is observed that the simulated terminal voltage profile 134 in each checking window matches well with the experimentally measured or benchmark terminal voltage curve, indicating that the updated battery model parameters 110B at each checkpoint estimated by the shallow estimation function 145 are accurate.

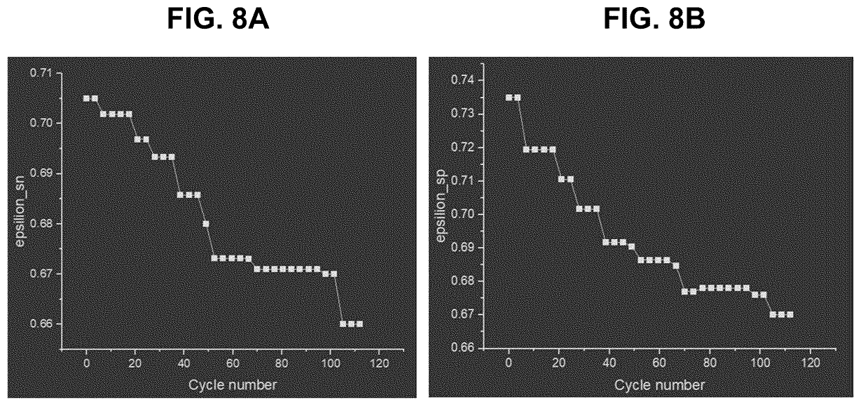

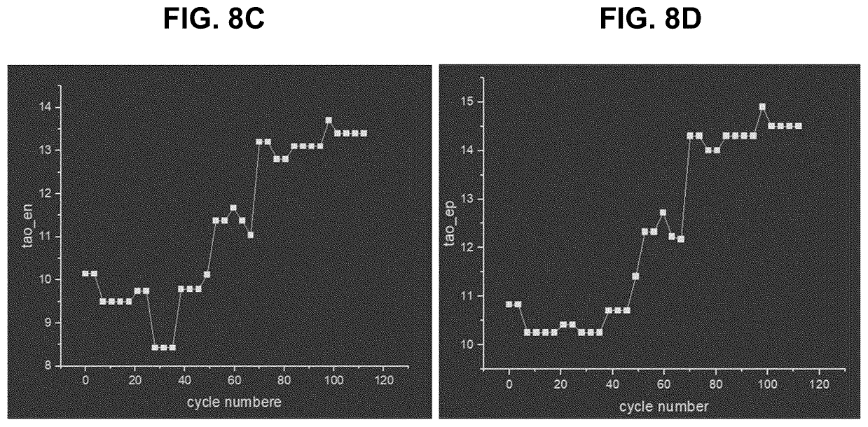

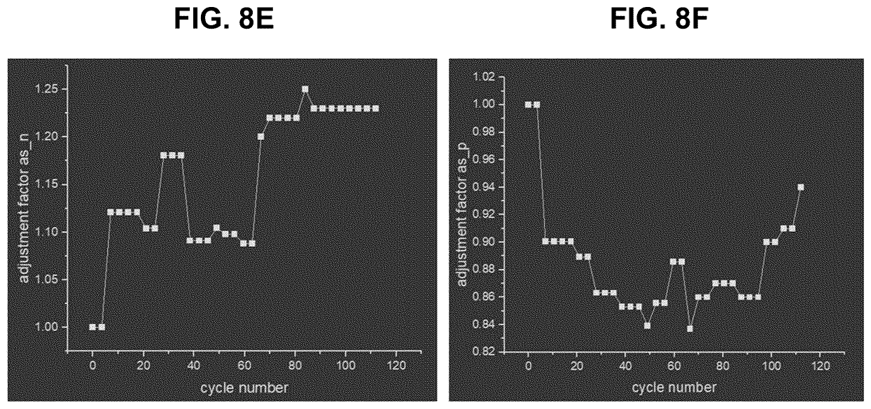

FIGS. 8A-8F illustrate the changing pattern of each battery model parameter 110B with cycling after a rough-fitting procedure (shown in white dot-dash lines) and a more fine-fitting procedure (shown in red dot-dash lines) based on the above simulations and battery model parameters estimations.

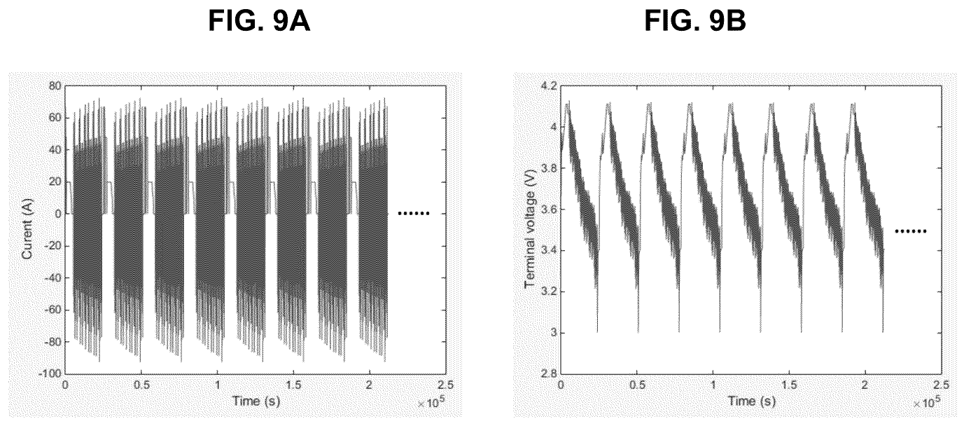

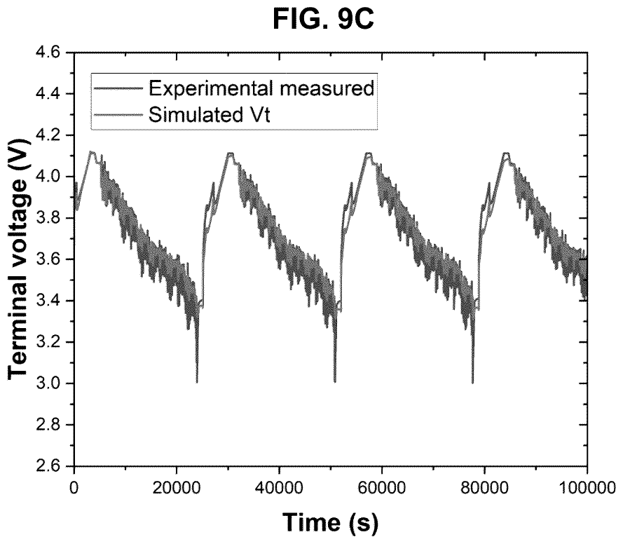

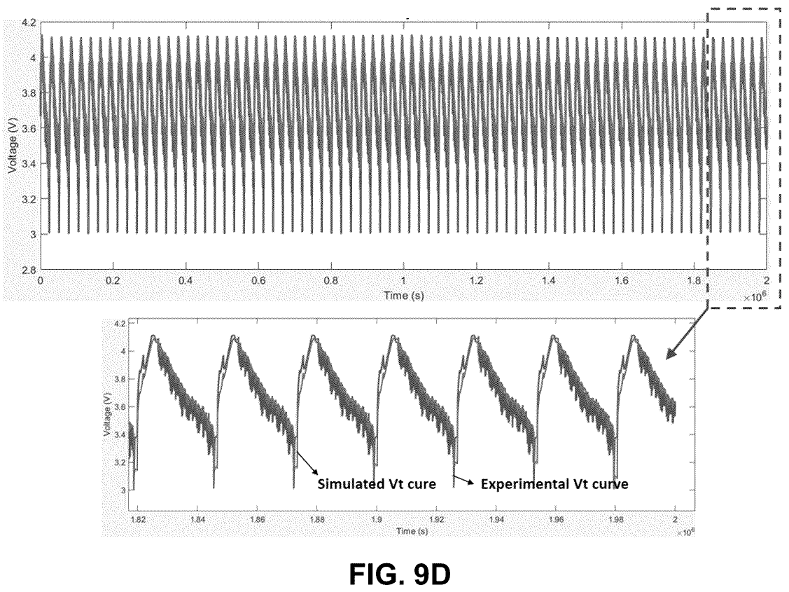

FIGS. 9A-9C illustrate tests results associating with estimating the degradation parameters 110A of a battery cell (e.g., battery 002). FIG. 9A illustrates the experimental input current data, and FIG. 9B illustrates the corresponding benchmark terminal voltage profile 133. The model parameters 110B are initially estimated using the fast or shallow estimation function 145. After optimization, the simulated terminal voltage profile 134 is generated using the reduced-order electrochemical model 140 based on the optimized model parameters 110B, and it is compared with the benchmark terminal voltage profile 133. As shown in FIG. 9C, the comparison shows a good matching phenomenon, indicating that the estimated battery initial parameters are accurate.

Next, the model parameters 110B may be set as constant, while the battery degradation parameters, including k_{neg,SEI}, k_{pos,SEI}, λ_{neg,SEI}, λ_{pos,SEI}, k_{decom} (electrolyte decomposition rate), k_{Mn,disso} (cathode Mn dissolution rate), and k_{Mn,dep} (anode Mn-ion deposition rate)) are estimated based on the experimental data (which has a length of 2×10⁷ seconds). When applying the fast or shallow estimation function 145 for estimating the degradation parameters 110A, the input current data can be preprocessed with a reduction metric value of 200. The preprocessed current data may then be input to the shallow estimation function 145, which includes a reduced-order electrochemical model 140 and an optimization function 170 for estimation. Using the optimized battery degradation parameters 110A (along with the battery model parameters 110B), the reduced-order electrochemical model 140 and optimization function 170 may generate a simulated terminal voltage profile 134.

FIG. 9D shows a comparison of the simulated terminal voltage profile 134 with the benchmark terminal voltage profile 133 based on the estimated degradation parameters 110A. In this figure, the benchmark terminal voltage profile is shown as a dark blue curve and the simulated terminal voltage profile is shown as the red curve). It can be seen that the simulated terminal voltage curve overall matches well with the benchmark terminal voltage curve (with an AAE of 45.6 mV), indicating the degradation parameters 110A estimated by shallow estimation function 145 have high accuracy. The degradation parameters 110A of the battery cell 105 can be identified as shown in Table 3 (below).

TABLE 3

| Battery degradation | |
|---|---|
| parameters | Most optimized value |
| k_{neg, SEI} | 4.108 × 10⁻¹⁴ m/s |
| k_{pos, SEI} | 3.016 × 10⁻¹⁶ m/s |
| λ_{neg, SEI} | 0.011970815511806185 |
| λ_{pos, SEI} | 0.01112722837747713 |
| k_{decom} | 4.814 × 10⁻¹³ m/s |
| k_{Mn, disso} | 2.163 × 10⁻¹³ m/s |
| k_{Mn, dep} | 9.769 × 10⁻¹⁰ m/s |

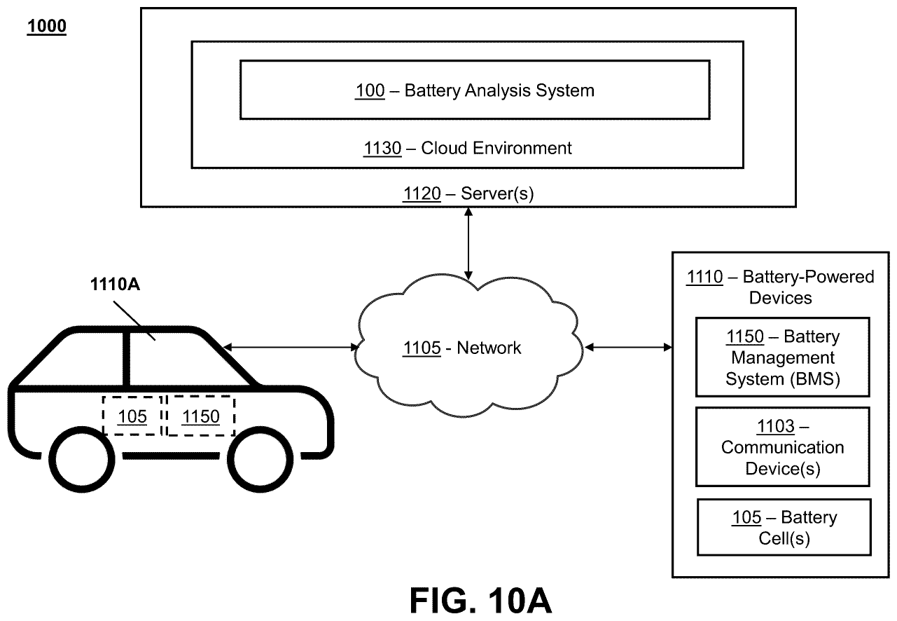

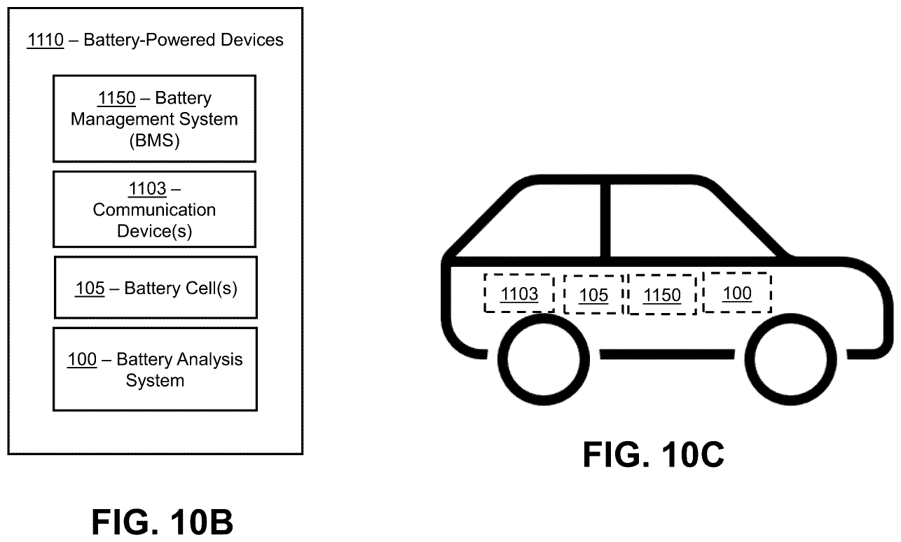

The battery analysis system 100 and related battery parameter estimation techniques described herein can be integrated into various systems, apparatuses, and/or devices. The manner in which the battery analysis system 100 is integrated into these systems, apparatuses, and/or devices. In some embodiments, the battery analysis system 100 can be integrated directly into systems, apparatuses, and/or devices to estimate battery parameters 110 for one or more battery cells 105 utilized to power the systems, apparatuses, and/or devices. Additionally, or alternatively, the battery analysis system 100 can be stored remotely and can communicate with these systems, apparatuses, and/or devices over a network to estimate battery parameters 110 for one or more battery cells 105 integrated into the systems, apparatuses, and/or devices. FIGS. 10A-10C illustrated exemplary configurations for integrating the battery analysis system 100 with these systems, apparatuses, and/or devices.

FIG. 10A is a block diagram of an exemplary system 1000 in accordance with certain embodiments. The system illustrates an exemplary network environment for deploying the battery analysis system 100 according to certain embodiments.

The system 1000 comprises one or more battery-powered devices 1110 (e.g., which may include one or more vehicles 1110A) and one or more servers 1120 that are in communication over a network 1105. A battery analysis system 100 is stored on, and executed by, the one or more servers 1120. The network 1105 may represent any type of communication network, e.g., such as one that comprises a local area network (e.g., a Wi-Fi network), a personal area network (e.g., a Bluetooth network), a wide area network, an intranet, the Internet, a cellular network, a television network, a satellite communication network, and/or other types of networks.

All the components illustrated in FIG. 10A, including the battery-powered devices 1110, vehicles 1110A, servers 1120, and battery analysis system 100 can be configured to communicate directly with each other and/or over the network 1105 via wired or wireless communication links, or a combination of the two. Each of the battery-powered devices 1110, vehicles 1110A, servers 1120, and battery analysis system 100 can include one or more storage devices 101 (e.g., RAM, ROM, PROM, etc.), one or more processing devices 102 (e.g., CPUs, GPCs, ASICs, processing circuits, etc.), and/or one or more communication devices 1103.

Each of the one or more communication devices 1103 can include wired and wireless communication devices and/or interfaces that enable communications using wired and/or wireless communication techniques. Wired and/or wireless communication can be implemented using any one or combination of wired and/or wireless communication network topologies (e.g., ring, line, tree, bus, mesh, star, daisy chain, hybrid, etc.) and/or protocols (e.g., personal area network (PAN) protocol(s), local area network (LAN) protocol(s), wide area network (WAN) protocol(s), cellular network protocol(s), powerline network protocol(s), etc.). Exemplary PAN protocol(s) can comprise Bluetooth, Zigbee, Wireless Universal Serial Bus (USB), Z-Wave, etc. Exemplary LAN and/or WAN protocol(s) can comprise Institute of Electrical and Electronic Engineers (IEEE) 802.3 (also known as Ethernet), IEEE 802.11 (also known as Wi-Fi), etc. Exemplary wireless cellular network protocol(s) can comprise Global System for Mobile Communications (GSM), General Packet Radio Service (GPRS), Code Division Multiple Access (CDMA), Evolution-Data Optimized (EV-DO), Enhanced Data Rates for GSM Evolution (EDGE), Universal Mobile Telecommunications System (UMTS), Digital Enhanced Cordless Telecommunications (DECT), Digital AMPS (IS-136/Time Division Multiple Access (TDMA)), Integrated Digital Enhanced Network (iDEN), Evolved High-Speed Packet Access (HSPA+), Long-Term Evolution (LTE), WiMAX, etc. The specific communication software and/or hardware can depend on the network topologies and/or protocols implemented. In certain embodiments, exemplary communication hardware can comprise wired communication hardware including, but not limited to, one or more data buses, one or more universal serial buses (USBs), one or more networking cables (e.g., one or more coaxial cables, optical fiber cables, twisted pair cables, and/or other cables). Further exemplary communication hardware can comprise wireless communication hardware including, for example, one or more radio transceivers, one or more infrared transceivers, etc. Additional exemplary communication hardware can comprise one or more networking components (e.g., modulator-demodulator components, gateway components, etc.). In certain embodiments, the one or more communication devices can include one or more transceiver devices, each of which includes a transmitter and a receiver for communicating wirelessly. The one or more communication devices 1103 also can include one or more wired ports (e.g., Ethernet ports, USB ports, auxiliary ports, etc.) and related cables and wires (e.g., Ethernet cables, USB cables, auxiliary wires, etc.).

In certain embodiments, the one or more communication devices 1103 additionally, or alternatively, can include one or more modem devices, one or more router devices, one or more access points, and/or one or more mobile hot spots. For example, modem devices may enable the battery-powered devices 1110, vehicles 1110A, servers 1120, and battery analysis system 100 to be connected to the Internet and/or other networks. The modem devices can permit bi-directional communication between the Internet (and/or other network) and the battery-powered devices 1110, vehicles 1110A, servers 1120, and battery analysis system 100. In certain embodiments, one or more router devices and/or access points may enable the battery-powered devices 1110, vehicles 1110A, servers 1120, and battery analysis system 100 to be connected to a LAN and/or other networks. In certain embodiments, one or more mobile hot spots may be configured to establish a LAN (e.g., a Wi-Fi network) that is linked to another network (e.g., a cellular network). The mobile hot spot may enable the battery-powered devices 1110, vehicles 1110A, servers 1120, and battery analysis system 100 to access the Internet and/or other networks.

In certain embodiments, a battery-powered device 1110 may generally represent any system, apparatus, or device that is equipped with one or more battery cells 105 and/or powered by one or more battery cells 105. The types of battery-powered devices 1110 may vary greatly.

In some examples, the battery-powered devices 1110 can include vehicles 1110A. The vehicles 1110A can include terrain-based vehicles (e.g., such as cars, trucks, motorcycles, etc.), water-based vehicles (e.g., boats, ships, jet skis, etc.), and/or aerial vehicles (e.g., planes, helicopters, spacecraft, etc.). The vehicles 1110A may comprise electric or hybrid vehicles, such as cars, trucks, planes, boats, or other vehicles that are solely or primarily powered by batteries comprising one or more battery cells 105. The vehicles 1110A also may include combustion-powered vehicles that utilize batteries to power onboard systems, such as electronics, displays, or equipment in the vehicle. Thus, in some cases, the battery cells 105 can power the propulsion or movement of the vehicles. Additionally, or alternatively, the battery cells 105 can power electronics or equipment incorporated into the vehicles 1110A.

In other examples, the battery-powered devices 1110 also may include other types of devices that are powered in whole or in part by one or more battery cells 105, such desktop computers, laptop computers, mobile devices (e.g., smart phones, personal digital assistants, tablet devices, vehicular computing devices, wearable devices, or any other device that is mobile in nature), gaming consoles and/or other types of devices.

Each of the battery-powered devices 1110 may include a battery management system (BMS) 1150. The BMS 1150 may be configured to monitor and control various aspects of the battery cells 105 within the battery-powered devices 1110. In some embodiments, the BMS 1150 may perform functions such as measuring and regulating the voltage, current, temperature, and state of charge of individual battery cells 105 or an entire battery pack comprising the battery cells 105. The BMS 1150 may also execute cell balancing operations to ensure uniform charge distribution across multiple battery cells 105, implement thermal management strategies to maintain optimal operating temperatures, and communicate with external systems to provide battery status information. Additionally, the BMS 1150 may be responsible for protecting the battery cells 105 from operating outside their safe operating area, detecting and preventing potential fault conditions, and optimizing battery performance and longevity.

The one or more servers 1120 may generally represent any type of computing device that is capable of communicating with other devices over a network 1105. In some embodiments, the one or more servers 1120 can comprise one or more mainframe computing devices, one or more virtual servers, one or more application servers, and/or one or more cloud-based servers. In some embodiments, the one or more servers 1120 may include one or more cloud-based servers that host a cloud environment 1130. The cloud environment 1130 may provide scalable, on-demand computing resources that enable efficient processing and storage of large datasets associated with battery parameter estimation, potentially allowing for faster and more cost-effective analysis compared to local computing solutions.

The battery analysis system 100 stored on the one or more servers 1120 and/or cloud environment 1130 can be configured to communicate with the battery-powered devices 1110 and/or vehicles 1110A over the network 1105. In certain embodiments, the battery analysis system 100 may interface with the battery-powered devices 1110 and/or BMSs 1150 integrated into the battery-powered devices 1110 over the network 1105, such as to receive input data 120 (e.g., current data 121) corresponding to the battery cells 105 included in the battery-powered devices 1110 and to provide real-time or near real-time battery parameter estimations to the battery-powered devices 1110.

In one example scenario, each of the battery-powered devices 1110 may continuously or periodically transmit the input data 120 (e.g., comprising voltage, current, resistance, or other measurements) to the remotely-stored battery analysis system 100 and, in response to receiving the input data 120, the battery analysis system 100 can utilize any of the parameter estimation techniques described in this disclosure to estimate battery parameters 110 corresponding to the battery cells 105 of each battery-powered device 1110. For example, the battery analysis system 100 may execute a shallow estimation function 145, a deep estimation function 155, or combination thereof to estimate battery parameters 110 corresponding to each of the battery cells 105 for each battery-powered device 1110. The estimated battery parameters 110 may be transmitted over the network 1105 to each of the battery-powered devices 1110. The BMS 1150 and/or other onboard system of the battery-powered devices 1110 may utilize the estimated battery parameters 110 to manage operation of the battery cells 105 utilized to power the battery-powered devices 1110.

Integrating the battery analysis system 100 into a server or cloud environment may offer several advantages in some embodiments. The cloud-based infrastructure can provide scalable computing resources, allowing for efficient processing of simulations to derive battery parameter estimation. In certain scenarios, this approach may enable faster analysis and more cost-effective solutions compared to localized computing implementations. Additionally, a cloud-based system may facilitate real-time or near real-time parameter estimations for multiple battery-powered devices simultaneously, as it can receive input data from various sources and quickly process it using the available computational power. Moreover, the centralized nature of a cloud environment may also allow for easier updates and maintenance of the battery analysis system, ensuring that all connected devices benefit from the latest improvements and optimizations in the parameter estimation algorithms. Furthermore, the cloud-based implementation may enable components of the system, such as the optimization functions 170, to be continuously refined and improved based on aggregated data accumulated from a multitude of battery-powered devices 1110, potentially enhancing the accuracy and efficiency of the battery parameter estimation process over time.

In certain embodiments, the battery analysis system 100 can additionally, or alternatively, be stored on, and executed by, the one or more battery-powered devices 1110. Thus, in some embodiments, the battery analysis system 100 can be stored as one or more server applications by one or more servers 1120 and, in other embodiments, the battery analysis system 100 can be stored as one or more local application (or one or more onboard applications) directly on the battery-powered devices 1110 themselves.

FIGS. 10B-10C illustrate embodiments in which the battery analysis system 100 is directly integrated with battery-powered devices 1110 and/or vehicles 1110A. In such embodiments, the functionalities of battery analysis system 100 can be integrated directly within a battery management system 1150 and/or the battery analysis system 100 may be a separate component that communicates with the battery management system 1150.

Integrating the battery analysis system 100 directly into a battery-powered device can offer several advantages in certain scenarios. This approach can enable real-time, on-device parameter estimation without relying on external network connectivity, which may be particularly beneficial in areas with limited or unreliable Internet or network access. Additionally, in some cases, this direct integration may also reduce latency in parameter estimations, allowing for more immediate adjustments to battery management strategies. Moreover, on-device analysis implementations can enhance data privacy and security by processing battery information locally rather than transmitting it to external servers. This localized approach may also reduce the computational load on centralized servers and minimize data transfer costs in some implementations.

Additionally, in some embodiments, the battery analysis system 100 can be implemented as a combination of a front-end application (e.g., which is stored on a battery-powered device 1110) and a back-end application (e.g., which is stored on one or more servers 1120). All functionalities of the battery analysis system 100 described herein can be executed by the front-end application, the back-end application, or a combination of both.

The battery analysis system 100 can be executed be stored on, and executed, by other devices as well. For example, in some cases, the battery analysis system 100 can be integrated a diagnostic tool or device that is physically separate from a battery-powered device 1110 and which can communicate with the battery-powered device 1110 to measure battery parameters 110 pertaining to the battery cells 105 included in the battery-powered device 1110.

It should be recognized that any features and/or functionalities described for an embodiment in this application can be incorporated into any other embodiment mentioned in this disclosure. Moreover, the embodiments described in this disclosure can be combined in various ways. Additionally, while the description herein may describe certain embodiments, features, or components as being implemented in software or hardware, it should be recognized that any embodiment, feature, or component that is described in the present application may be implemented in hardware, software, or a combination of the two.

While various novel features of the invention have been shown, described, and pointed out as applied to particular embodiments thereof, it should be understood that various omissions and substitutions, and changes in the form and details of the systems and methods described and illustrated, may be made by those skilled in the art without departing from the spirit of the invention. Amongst other things, the steps in the methods may be carried out in different orders in many cases where such may be appropriate. Those skilled in the art will recognize, based on the above disclosure and an understanding of the teachings of the invention, that the particular hardware and devices that are part of the system described herein, and the general functionality provided by and incorporated therein, may vary in different embodiments of the invention. Accordingly, the description of system components are for illustrative purposes to facilitate a full and complete understanding and appreciation of the various aspects and functionality of particular embodiments of the invention as realized in system and method embodiments thereof. Those skilled in the art will appreciate that the invention can be practiced in other than the described embodiments, which are presented for purposes of illustration and not limitation. Variations, modifications, and other implementations of what is described herein may occur to those of ordinary skill in the art without departing from the spirit and scope of the present invention and its claims.

1. A method for estimating one or more battery parameters:
receiving, by a battery analysis system, current data corresponding to a battery cell;
generating, by a preprocessing function of the battery analysis system, preprocessed current data based on the current data, the preprocessed current data having a reduced frequency and a reduced amplitude relative to the current data;
receiving, by a shallow estimation function of the battery analysis system, the preprocessed current data;
executing the shallow estimation function to estimate one or more battery parameters corresponding to the battery cell, at least in part, by applying the preprocessed current data as an input to a simulation executed by a reduced-order electrochemical model; and
determining a diagnostic assessment corresponding to the battery cell based, at least in part, on the one or more battery parameters.

2. The method of claim 1, wherein the shallow estimation function utilizes an optimization function that cooperates with the reduced-order electrochemical model to estimate one or more battery parameters, and generating the preprocessed current data prior to execution of the shallow estimation function operates to narrow down a parameter range that is utilized by the optimization function in estimating the one or more battery parameters and utilized by the reduced-order electrochemical model in executing the simulation.

3. The method of claim 1, further comprising:
determining if the one or more battery parameters estimated using the shallow estimation function are sufficiently accurate; and
in response to determining that the one or more battery parameters are not sufficiently accurate, executing a deep estimation function that utilizes a full-order electrochemical model to refine the one or more battery parameters corresponding to the battery cell.

4. The method of claim 3, wherein the one or more battery parameters estimated by the shallow estimation function are applied to narrow a parameter range for the deep estimation function.

5. The method of claim 1, further comprising:
receiving reference voltage data comprising charging/discharging data derived from one or more battery-powered devices;
determining a benchmark terminal voltage profile based, at least in part, on the reference voltage data;
generating, using the reduced-order electrochemical model, a simulated terminal voltage profile based on the preprocessed current data; and
comparing the simulated terminal voltage profile with the benchmark terminal voltage profile to assess a sufficiency of the preprocessed current data.

6. The method of claim 5, wherein:
the preprocessed current data is generated according to a reduction metric that quantifies a degree to which a frequency and an amplitude of the current data is reduced; and
in response to determining that a difference between the simulated terminal voltage profile and the benchmark terminal voltage profile satisfies an error threshold, the preprocessed current data generated according to the reduction metric is determined to be acceptable for usage in estimating the one or more battery parameters corresponding to the battery cell.

7. The method of claim 5, wherein:
the preprocessed current data is generated according to a first reduction metric that quantifies a degree to which a frequency and an amplitude of the current data is reduced; and
in response to determining that a difference between the simulated terminal voltage profile and the benchmark terminal voltage profile does not satisfy an error threshold, new preprocessed current data is generated according to a second reduction metric that reduces the frequency and the amplitude of the current data to a lesser extent relative to the first reduction metric.

8. The method of claim 7, wherein the preprocessed current data is iteratively refined according to a new reduction metric until the difference between the simulated terminal voltage profile and the benchmark terminal voltage profile satisfies the error threshold.

9. The method of claim 1, wherein:
the battery analysis system is configured to estimate the one or more battery parameters for one or more battery cells included in an electric vehicle; and
the battery analysis system is integrated directly into the electric vehicle or is integrated into a cloud environment that is in communication with the electric vehicle over a network.

10. The method of claim 1, wherein the one or more battery parameters include at least one of:
a degradation parameter corresponding to the battery cell;
a thermal parameter corresponding to the battery cell;
a model parameter corresponding to the battery cell; or
a state-of-health (SOH) parameter corresponding to the battery cell.

11. A system for estimating one or more battery parameters comprises:
one or more processing devices; and
one or more non-transitory storage devices storing computing instructions that, when executed by the one or more processing devices, cause the one or more processing devices to perform operations comprising:
receiving, by a battery analysis system, current data corresponding to a battery cell;
generating, by a preprocessing function of the battery analysis system, preprocessed current data based on the current data, the preprocessed current data having a reduced frequency and a reduced amplitude relative to the current data;
receiving, by a shallow estimation function of the battery analysis system, the preprocessed current data;
executing the shallow estimation function to estimate one or more battery parameters corresponding to the battery cell, at least in part, by applying the preprocessed current data as an input to a simulation executed by a reduced-order electrochemical model; and
determining a diagnostic assessment corresponding to the battery cell based, at least in part, on the one or more battery parameters.

12. The system of claim 11, wherein the shallow estimation function comprises an optimization function that works in conjunction with the reduced-order electrochemical model to estimate one or more battery parameters, and generating the preprocessed current data prior to execution of the shallow estimation function operates to narrow down a parameter range that is utilized by the optimization function in estimating the one or more battery parameters and utilized by the reduced-order electrochemical model in executing the simulation.

13. The system of claim 11, wherein execution of the computing instructions further causes the one or more processing devices to perform operations comprising:
determining if the one or more battery parameters estimated using the shallow estimation function are sufficiently accurate; and
in response to determining that the one or more battery parameters are not sufficiently accurate, executing a deep estimation function that utilizes a full-order electrochemical model to refine the one or more battery parameters corresponding to the battery cell.

14. The system of claim 13, wherein the one or more battery parameters estimated by the shallow estimation function are applied to narrow a parameter range for the deep estimation function.

15. The system of claim 11, wherein execution of the computing instructions further causes the one or more processing devices to perform operations comprising:
receiving reference voltage data comprising charging/discharging data derived from one or more battery-powered devices;
determining a benchmark terminal voltage profile based, at least in part, on the reference voltage data;
generating, using the reduced-order electrochemical model, a simulated terminal voltage profile based on the preprocessed current data; and
comparing the simulated terminal voltage profile with the benchmark terminal voltage profile to assess a sufficiency of the preprocessed current data.

16. The system of claim 15, wherein:
the preprocessed current data is generated according to a reduction metric that quantifies a degree to which a frequency and an amplitude of the current data is reduced; and
the battery analysis system is configured to evaluate the preprocessed current data such that:
in response to determining that a difference between the simulated terminal voltage profile and the benchmark terminal voltage profile satisfies an error threshold, the preprocessed current data generated according to the reduction metric is determined to be acceptable for usage in estimating the one or more battery parameters corresponding to the battery cell; or
in response to determining that the difference between the simulated terminal voltage profile and the benchmark terminal voltage profile does not satisfy the error threshold, the preprocessed current data is iteratively refined according to a new reduction metric until the difference between the simulated terminal voltage profile and the benchmark terminal voltage profile satisfies the error threshold.

17. The system of claim 11, wherein the battery analysis system is configured to estimate the one or more battery parameters for one or more battery cells included in an electric vehicle, and the battery analysis system is integrated directly into the electric vehicle or is integrated into a cloud environment that is in communication with the electric vehicle.

18. A method for estimating one or more battery parameters comprising:
receiving, by a shallow estimation function, current data corresponding to a battery cell;
executing the shallow estimation function to estimate one or more battery parameters corresponding to the battery cell, at least in part, by applying the current data as an input to a simulation executed by a reduced-order electrochemical model;
receiving, by a deep estimation function, the one or more battery parameters estimated using the shallow estimation function;
executing the deep estimation function to refine the one or more battery parameters corresponding to the battery cell, wherein:
the deep estimation function utilizes a full-order electrochemical model to refine the one or more battery parameters corresponding to the battery cell; and
the one or more battery parameters estimated by the shallow estimation function are applied to narrow a parameter range for the deep estimation function; and
determining a diagnostic assessment corresponding to the battery cell based, at least in part, on the one or more battery parameters.

19. The method of claim 18, wherein the current data is preprocessed prior to execution of the shallow estimation function or the deep estimation function to reduce a frequency and an amplitude of the current data.

20. The method of claim 19, wherein:
the current data is preprocessed according to a reduction metric that quantifies a degree to which a frequency and an amplitude of the current data are reduced; and
the current data is iteratively refined according to a new reduction metric until an error threshold is satisfied.
